(19) United States
(12) Patent Application Publication
(10) Pub. No.: US 2012/0126381 A1
(43) Pub. Date: May 24, 2012

(54) ADHESIVE FILM FOR SEMICONDUCTOR DEVICE, AND SEMICONDUCTOR DEVICE

(76) Inventors: Daisuke UENDA, Ibaraki-shi (JP); Takeshi MATSUMURA, Ibaraki-shi (JP); Koichi INOUE, Ibaraki-shi (JP); Miki MORITA, Ibaraki-shi (JP)

(21) Appl. No.: 13/298,687

(22) Filed: Nov. 17, 2011

(30) Foreign Application Priority Data
Nov. 18, 2010 (JP) 2010-258074

(51) Int. Cl. H01L 23/552; B32B 7/12

(52) U.S. Cl. 257/659; 428/343; 257/E23.114

(57) ABSTRACT

An object of the present invention is to decrease the influence of an electromagnetic wave emitted from one semiconductor chip on other semiconductor chips in the same package, amounted substrate, adjacent devices, and the package. The present invention provides an adhesive film for a semiconductor device having an adhesive layer and an electromagnetic wave shielding layer, in which the attenuation of the electromagnetic wave that penetrates the adhesive film for a semiconductor device is 3 dB or more in at least a portion of the frequency range of 50 MHz to 20 GHz.

### BACKGROUND OF THE INVENTION

1. Field of the Invention

The present invention relates to an adhesive film for a semiconductor device used in manufacturing a semiconductor device. The present invention also relates to a semiconductor device having the adhesive film for a semiconductor device.

2. Description of the Related Art

In recent years, the wiring width of power supply lines that are arranged across the whole area of the main surface of a semiconductor chip (a semiconductor element) and the space between signal lines have become narrower in order to correspond to demands for microfabrication and high function of semiconductor devices. Because of this, an increase of impedance and an interference between signals in signal lines of different nodes occur, which have become an impediment to sufficient performance in operating speed, the degree of operating voltage margin, and anti-electrostatic breakdown strength of the semiconductor chip.

Conventionally, a package structure in which semiconductor chips are laminated has been proposed to solve the above-described problems (refer to Japanese Patent Application Laid-Open Nos. 55-111151 and 2002-261233, for example).

On the other hand, the frequency range of an electromagnetic wave (noise) that is emitted from a semiconductor chip has become varied due to the diversification of electronic components in recent years. When the semiconductor elements are laminated as in the above-described package structure, there is a possibility that the electromagnetic wave emitted from one semiconductor chip has a bad influence on other semiconductor chips, the substrate, adjacent devices, and the package.

An electromagnetic wave shielding sheet for adhering a semiconductor element having a pressure-sensitive adhesive layer on both outermost surfaces of a laminated body consisting of an electrical insulation layer and a ferrite layer is disclosed in Japanese Patent No. 4133637. It is also described in Japanese Patent No. 4133637 that leakage of an electrical signal is attenuated by the magnetic loss characteristic of the ferrite layer of the electromagnetic wave shielding sheet for adhering a semiconductor element.

Further, a semiconductor device in which a first magnetic shielding material is arranged between a die pad and the backside of a semiconductor chip and a second magnetic shielding material is arranged on the main surface of the semiconductor chip is disclosed in Japanese Patent Application Laid-Open No. 2010-153760. It is also described in Japanese Patent Application Laid-Open No. 2010-153760 that resistance of the semiconductor device to an external magnetic field is improved.

### SUMMARY OF THE INVENTION

The thickness of the ferrite layer in the electromagnetic wave shielding sheet for adhering a semiconductor element of Japanese Patent No. 4133637 that shields an electromagnetic wave is 100 nm to 10 μm. However, there is no substantial shielding effect for an electromagnetic wave having a frequency of 100 kHz or more with the thickness described in that patent, and the sheet does not function well as an electromagnetic wave shielding material.

Further, only a laminate structure of a semiconductor device is disclosed in Japanese Patent Application Laid-Open No. 2010-153760, and what means is used for shielding an electromagnetic wave of what frequency range is not disclosed.

The present inventors investigated an adhesive film for a semiconductor device and a semiconductor device having the adhesive film for a semiconductor device to solve the above-described conventional problems. As a result, they found that the influence of an electromagnetic wave emitted from one semiconductor chip on other semiconductor chips in the same package, amounted substrate, adjacent devices, and the package can be decreased by adopting the following configuration, and completed the present invention.

That is, the adhesive film for a semiconductor device according to the present invention is an adhesive film for a semiconductor device having an adhesive layer and an electromagnetic wave shielding layer, wherein the attenuation of the electromagnetic wave that penetrates the adhesive film for a semiconductor device is 3 dB or more in at least a portion of the frequency range of 50 MHz to 20 GHz.

According to the above-described configuration, the attenuation of the electromagnetic wave that penetrates the adhesive film for a semiconductor device is 3 dB or more in at least a portion of the relatively high frequency range of 50 MHz to 20 GHz, and the electromagnetic wave can be efficiently shielded. Therefore, the influence of an electromagnetic wave emitted from one semiconductor element on other semiconductor chips, the substrate, adjacent devices, and the package can be decreased. Because a relatively high frequency band (for example, a 2 GHz band or a 5.8 GHz band) is used in portable terminals such as a portable telephones and electronic toll collection (ETC) systems, noise from a chip that is generated during communication also is in the high frequency band.

According to the above-described configuration, an electromagnetic wave of such high frequency band can be efficiently shielded in particular.

The semiconductor device according to the present invention is a semiconductor device having an adherend and a semiconductor element, wherein the adhesive film for a semiconductor device is provided between the adherend and the semiconductor element to solve the above-described problems.

Another semiconductor device according to the present invention is a semiconductor device having two or more semiconductor elements, wherein the adhesive film for a semiconductor device is provided between one of the semiconductor elements and the remainder of the semiconductor elements to solve the above-described problems.

Another semiconductor device according to the present invention is a semiconductor device in which a semiconductor element is a flip-chip connected to an adherend, wherein the adhesive film for a semiconductor device is provided on the semiconductor element to solve the above-described problems.

### BRIEF DESCRIPTION OF THE DRAWINGS

FIG. 1 is a sectional schematic drawing showing a die bond film according to one embodiment of the present invention;

FIG. 2 is a sectional schematic drawing showing the die bond film according to another embodiment of the present invention;

FIG. 3 is a sectional schematic drawing showing one example of a dicing die bond film in which the die bond film shown in FIG. 2 is laminated;

FIG. 4 is a sectional schematic drawing showing one example of another dicing die bond film in which the die bond film shown in FIG. 2 is laminated;

FIG. 5 is a sectional schematic drawing showing an example in which a semiconductor chip is mounted interposing the die bond film in the dicing die bond film shown in FIG. 3;

FIG. 6 is a sectional schematic drawing showing an example in which a semiconductor chip is three dimensionally mounted interposing the die bond film in the dicing die bond film shown in FIG. 3;

FIG. 7 is a sectional schematic drawing showing one example of a flip-chip type semiconductor device using a film for the backside of the flip-chip type semiconductor;

FIG. 8 is a graph showing a measurement result of electromagnetic wave attenuation (dB) of the adhesive film for a semiconductor device according to Example 1;

FIG. 9 is a graph showing a measurement result of electromagnetic wave attenuation (dB) of the adhesive film for a semiconductor device according to Example 2;

FIG. 10 is a graph showing a measurement result of electromagnetic wave attenuation (dB) of the adhesive film for a semiconductor device according to Example 3;

FIG. 11 is a graph showing a measurement result of electromagnetic wave attenuation (dB) of the adhesive film for a semiconductor device according to Example 4;

FIG. 12 is a graph showing a measurement result of electromagnetic wave attenuation (dB) of the adhesive film for a semiconductor device according to Example 5;

FIG. 13 is a graph showing a measurement result of electromagnetic wave attenuation (dB) of the adhesive film for a semiconductor device according to Example 6;

FIG. 14 is a graph showing a measurement result of electromagnetic wave attenuation (dB) of the adhesive film for a semiconductor device according to Comparative Example 1; and

FIG. 15 is a graph showing a measurement result of electromagnetic wave attenuation (dB) of the adhesive film for a semiconductor device according to Comparative Example 2.

### DESCRIPTION OF THE REFERENCE NUMERALS

1 Base
2 Pressure-sensitive adhesive layer
4 Semiconductor wafer
5 Semiconductor chip
6 Adherend
7 Bonding wire
8 Sealing resin
10, 12 Dicing die bond film
11 Dicing film
15 Semiconductor chip
30, 32 Adhesive layer
31 Electromagnetic wave shielding layer
40, 41, 41′ Die bond film (adhesive film for semiconductor device)
44 Film for the backside of flip-chip type semiconductor (adhesive film for semiconductor device)
50 Flip-chip type semiconductor device

### DESCRIPTION OF THE PREFERRED EMBODIMENTS

The film for a semiconductor device of the present invention is used in a semiconductor device, and can be used as a die bond film, a film for the backside of a flip-chip type semiconductor, and a film that is pasted to a semiconductor wafer when manufacturing a wafer label package. First, a case is explained below in which the film for a semiconductor device is a die bond film.

### (Die Bond Film)

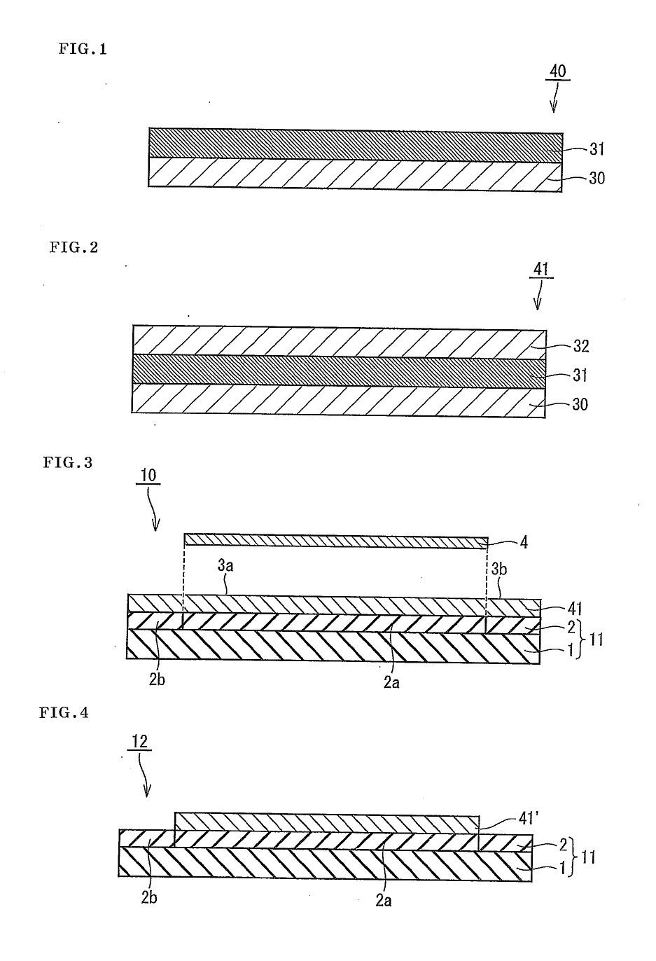

FIG. 1 is a sectional schematic drawing showing a die bond film according to one embodiment of the present invention and FIG. 2 is a sectional schematic drawing showing the die bond film according to another embodiment. As shown in FIG. 1, a die bond film 40 has a configuration in which an electromagnetic wave shielding layer 31 is laminated on an adhesive layer 30. The die bond film according to the present invention may have a configuration in which an adhesive layer 32 is further laminated on the magnetic wave shielding layer 31 as in a die bond film 41 shown in FIG. 2. The die bond film according to the present invention is not limited to the die bond films 40 and 41 as long as it has an adhesive layer and an electromagnetic wave shielding layer, and it may have other layers besides the adhesive layer and the electromagnetic wave shielding layer, for example.

The attenuation of the electromagnetic wave that penetrates the die bond films 40 and 41 is 3 dB or more in at least a portion of the frequency range of 50 MHz to 20 GHz. The frequency range is preferably in a range of 80 MHz to 19 GHz, and more preferably in a range of 100 MHz to 18 GHz. The attenuation is preferably 4 dB or more, and more preferably 5 dB or more. Because the attenuation of the electromagnetic wave that penetrates the die bond films 40 and 41 is 3 dB or more in at least a portion of the relatively high frequency range of 50 MHz to 20 GHz, the electromagnetic wave can be efficiently shielded. Therefore, the influence of an electromagnetic wave emitted from one semiconductor element on other semiconductor elements, the substrate, adjacent devices, and the package can be decreased.

Examples of the electromagnetic wave shielding layer 31 include a conductive layer, a dielectric layer, and a magnetic layer. An example of the conductive layer is a layer having an inorganic conductive material or an organic conductive material. Examples of the inorganic conductive material include at least one metal element selected from the group consisting of Li, Na, K, Rb, Cs, Ca, Sr, Ba, Ra, Be, Mg, Zn, Cd, Hg, Al, Ga, In, Y, La, Ce, Pr, Nd, Sm, Eu, Ti, Zr, Sn, Hf, Pb, Th, Fe, Co, N, V, Nb, Ta, Cr, Mo, W, U, Mn, Re, Cu, Ag, Au, Ru, Rh, Pd, Os, Ir, and Pt, oxides of these metal elements, and alloys of these metal elements. Examples of the organic conductive material include polyacetylene, polyparaphenylene, polyaniline, polythiophene, polyparaphenylenevinylene, and polypyrrole. The organic conductive materials can be used alone or two types or more can be used together. Further, the inorganic conductive materials and the organic conductive materials can be used together. The conductive layer may be a layer consisting only of a conductive material such as a metal foil or a vapor deposited film, or it may be a layer in which the inorganic conductive material or the organic conductive material is compounded in a resin. Among these, conductive layers having an electric conductivity of 10×10¹ to 10×10⁷ S/m are preferable, conductive layers having an electric conductivity of 5×10² to 5×10⁷ S/m are more preferable, and conductive layers having an electric conductivity of 10×10² to 1×10⁷ S/m are further preferable. The conductive layer can attenuate an electromagnetic wave due to reflection loss. The metal foil consists of the above-described inorganic conductive materials, and is manufactured by thinly expanding the inorganic conductive materials (about 0.1 to 100 μm, for example).

The material used in the dielectric layer is not especially limited. Examples thereof include synthetic resins such as polyethylene, polyester, polystyrene, polyimide, polycarbonate, polyamide, polysulfone, polyethersulfone, polyvinyl chloride, and epoxy, and various synthetic rubber materials such as polyisoprene rubber, polystyrene butadiene rubber, polybutadiene rubber, chloroprene rubber, acrylonitrile butadiene rubber (NBR), butyl rubber, acrylic rubber, ethylene propylene rubber, and silicon rubber. Other examples include materials in which inorganic materials such as carbon, titanium oxide, alumina, barium titanate, and Rochelle salt are added into these resins. Among these, dielectric layers having a relative permittivity of 1.0 to 4000 are preferable, dielectric layers having a relative permittivity of 1.0 to 1000 are more preferable, and dielectric layers having a relative permittivity of 1.0 to 100 are further preferable. The dielectric layer can attenuate an electromagnetic wave due to dielectric loss.

The magnetic particles used in the magnetic layer are not especially limited. Examples thereof include hematite (Fe₂O₃; magnetite (Fe₃O₄); various ferrites represented by the general formulae MFe₂O₄ and MO.nFe₂O₃ (wherein M is a divalent metal particle and examples thereof include Mn, Co, Ni, Cu, Zn, Ba, and Mg; n is a positive number: and M may be of the same type or a different type when repeated); silicon steel powder; various metal powders and alloy powders thereof such as permalloy (Fe—Ni alloy), Co-based amorphous alloy, Sendust (Fe—Al—Si alloy), alperm, supermalloy, permendar, and perminvar; and magnetic powder. Finemet (registered tradename) manufactured by Hitachi Metals, Ltd. can also be used. These can be used alone or two types or more can be used together. The magnetic layer can be a layer in which the above-described magnetic particles are compounded in a resin. The magnetic layer can attenuate an electromagnetic wave due to a magnetic loss. The electromagnetic wave shielding effect can be exhibited further by using a layer in which the conductive materials (the above-described organic conductive materials and inorganic conductive materials) and the above-described magnetic particles are compounded as the electromagnetic wave shielding layer 31.

The thickness of the electromagnetic wave shielding layer 31 is not especially limited. It can be selected from a range of 0.001 to 10000 μm, preferably 0.005 to 900 μm, and more preferably 0.01 to 800 μm. However, the thickness of the electromagnetic wave shielding layer 31 differs according to the frequency of the electromagnetic wave to be shielded when the electromagnetic wave shielding characteristic is given by the dielectric layer or the magnetic layer. In general, the thickness is preferably ¼ or more of the wavelength (λ) of the electromagnetic wave to be shielded.

The 180 degree peeling strength between the adhesive layer 30 and the electromagnetic wave shielding layer 31 and the 180 degree peeling strength between the adhesive layer 32 and the electromagnetic wave shielding layer 31 are preferably 0.5 N/10 mm or more, more preferably 0.8 N/10 mm, and further preferably 1.0 N/10 mm or more. By making the 180 degree peeling strength 0.5 N/10 mm or more, interlayer peeling becomes difficult to occur and the yield can be improved.

The 180 degree peeling strength can be measured as follows. First, the adhesive layer is lined with a pressure-sensitive adhesive tape (BT-315 manufactured by Nitto Denko Corporation) and cut into a piece of 10×100 mm. Next, the electromagnetic wave shielding layer is lined with a pressure-sensitive adhesive tape (BT-315 manufactured by Nitto Denko Corporation) and cut into a piece of 10×100 mm. Then, the cut adhesive layer and the cut electromagnetic wave shielding layer are pasted together using a laminator (MRK-600 manufactured by MCK Co., Ltd.) under conditions of 50° C., 0.5 MPa, and 10 mm/sec. After that, the resultant is left for 20 minutes under an atmosphere of normal temperature (25° C.), and a test piece is obtained. The 180 degree peeling force between the adhesive layer and the electromagnetic wave shielding layer is measured using a tensile tester (AGS-J manufactured by Shimadzu Corporation).

An example of the adhesive composition that constitutes the adhesive layers 30 and 32 is an adhesive composition in which a thermoplastic resin and a thermosetting resin are used together. The adhesive layers 30 and 32 may have the same composition or different compositions from each other.

Examples of the above-mentioned thermosetting resin include phenol resin, amino resin, unsaturated polyester resin, epoxy resin, polyurethane resin, silicone resin, and thermosetting polyimide resin. These resins may be used alone or in combination of two or more thereof. Particularly preferable is epoxy resin, which contains ionic impurities which corrode semiconductor elements in only a small amount. As the curing agent of the epoxy resin, phenol resin is preferable.

The epoxy resin may be any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, particularly preferable are Novolak type epoxy resin, biphenyl type epoxy resin, tris-hydroxyphenylmethane type epoxy resin, and tetraphenylolethane type epoxy resin, since these epoxy resins are rich in reactivity with phenol resin as an agent for curing the epoxy resin and are superior in heat resistance and so on.

Two types of epoxy resins, one that is solid at normal temperature and one that is liquid at normal temperature, can be used together as the epoxy resin. By adding an epoxy resin that is liquid at normal temperature to an epoxy resin that is solid at normal temperature, vulnerability when forming a film can be improved and workability can be improved.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin and nonylphenol Novolak resin; resol type phenol resins; and polyoxystyrenes such as poly(p-oxystyrene). These may be used alone or in combination of two or more thereof. Among these phenol resins, phenol Novolak resin and phenol aralkyl resin are particularly preferable, since the connection reliability of the semiconductor device can be improved.

About the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, curing reaction therebetween does not advance sufficiently so that properties of the cured epoxy resin easily deteriorate.

Examples of the thermoplastic resin include natural rubber, butyl rubber, isoprene rubber, chloroprene rubber, ethylene/vinyl acetate copolymer, ethylene/acrylic acid copolymer, ethylene/acrylic ester copolymer, polybutadiene resin, polycarbonate resin, thermoplastic polyimide resin, polyamide resins such as 6-nylon and 6,6-nylon, phenoxy resin, acrylic resin, saturated polyester resins such as PET and PBT, polyamideimide resin, and fluorine-contained resin. These thermoplastic resins may be used alone or in combination of two or more thereof. Of these thermoplastic resins, acrylic resin is particularly preferable since the resin contains ionic impurities in only a small amount and has a high heat resistance so as to make it possible to ensure the reliability of the semiconductor element.

The acrylic resin is not limited to any especial kind, and may be, for example, a polymer comprising, as a component or components, one or more esters of acrylic acid or methacrylic acid having a linear or branched alkyl group having 30 or less carbon atoms, in particular, 4 to 18 carbon atoms. Examples of the alkyl group include methyl, ethyl, propyl, isopropyl, n-butyl, t-butyl, isobutyl, amyl, isoamyl, hexyl, heptyl, cyclohexyl, 2-ethylhexyl, octyl, isooctyl, nonyl, isononyl, decyl, isodecyl, undecyl, lauryl, tridecyl, tetradecyl, stearyl, octadecyl, and dodecyl groups.

A different monomer which constitutes the above-mentioned polymer is not limited to any especial kind, and examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl(meth)acrylate, 2-hydroxypropyl(meth)acrylate, 4-hydroxybutyl (meth)acrylate, 6-hydroxyhexyl(meth)acrylate, 8-hydroxyoctyl(meth)acrylate, 10-hydroxydecyl (meth)acrylate, 12-hydroxylauryl(meth)acrylate, and (4-hydroxymethylcyclohexyl) methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl (meth)acrylate, and (meth)acryloyloxynaphthalenesulfonic acid; and monomers which contain a phosphoric acid group, such as 2-hydroxyethylacryloyl phosphate. Among these, a carboxyl group-containing monomer is preferable from the viewpoint that the tensile storage modulus Ea of the die bond film can be set at a preferred value.

The compounding ratio of the thermosetting resin is not especially limited as long as it is a level at which the adhesive layers 30 and 32 exhibit a function as a thermosetting type when they are heated under a prescribed condition. However, the compounding ratio is preferably in a range of 5 to 60% by weight and more preferably 10 to 50% by weight.

Further, a polyimide resin can be used alone besides combination use with other resins as a thermosetting polyimide resin or a thermoplastic polyimide resin as the adhesive composition that constitutes the adhesive layers 30 and 32. The polyimide resin is a heat resistant resin that can be generally obtained by a dehydration condensation (imidization) of polyamic acid that is a precursor thereof. The polyamic acid can be obtained by reacting a diamine component with an acid anhydride component in an appropriate organic solvent at a substantially equal molar ratio.

Examples of the diamine include aliphatic diamines and aromatic diamines. Examples of the aliphatic diamines include ethylenediamine, hexamethylenediamine, 1,8-diaminooctane, 1,10-diaminodecane, 1,12-diaminododecane, 4,9-dioxa-1,12-diaminododecane, and 1,3-bis(3-aminopropyl)-1,1,3,3-tetramethyldisiloxane(α,ω-b isaminopropyltetramethyldisiloxane). The molecular weight of the aliphatic diamine is normally 50 to 1,000,000 and preferably 100 to 30,000.

Examples of the aromatic diamines include 4,4′-diaminodiphenylether, 3,4′-diaminodiphenylether, 3,3′-diaminodiphenylether, m-phenylenediamine, p-phenylenediamine, 4,4′-diaminodiphenylpropane, 3,3′-diaminodiphenylmethane, 4,4′-diaminodiphenylsulfide, 3,3′-diaminodiphenylsulfide, 4,4′-diaminodiphenylsulfone, 3,3′-diaminodiphenylsulfone, 1,4-bis(4-aminophenoxy)benzene, 1,3-bis(4-aminophenoxy)benzene, 1,3-bis(3-aminophenoxy)benzene, 1,3-bis(4-aminophenoxy)-2,2-dimethylpropane, and 4,4′-diaminobenzophenone.

Various acid anhydrides can be used. An example thereof is a tetracarboxylic dianhydride. Examples of the tetracarboxylic dianhydride include a 3,3′,4,4′-biphenyltetracarboxylic dianhydride, a 2,2′,3,3′-biphenyltetracarboxylic dianhydride, 3,3′,4,4′-benzophenonetetracarboxylic dianhydride, a 2,2′,3,3′-benzophenonetetracarboxylic dianhydride, a 4,4′-oxydiphthalic dianhydride, a 2,2-bis(2,3-dicarboxyphenyl) hexafluoropropane dianhydride, a 2,2-bis(3,4-dicarboxyphenyl)hexafluoropropane dianhydride (6FDA), a bis(2,3-dicarboxyphenyl)methane dianhydride, a bis(3,4-dicarboxyphenyl)methane dianhydride, a bis(2,3-dicarboxyphenyl)sulfone dianhydride, a bis(3,4-dicarboxyphenyl)sulfone dianhydride, a pyromellitic dianhydride, and an ethyleneglycol bistrimellitic dianhydride. These may be used alone or two types or more may be used together.

The solvent in which the diamine and the acid anhydride are reacted is not especially limited. Examples thereof include N,N-dimethylacetamide, N-methyl-2-pyrrolidone, N,N-dimethylformamide, and cyclopentanone. These can be used by appropriately mixing with a non-polar solvent such as toluene or xylene to adjust solubility of the raw material and the resin.

Examples of a method of imidizing polyamic acid include a heat imidization method, an azeotropic dehydration method, and a chemical imidization method. Among these, a heat imidization method is preferable, and the heating temperature is preferably 150° C. or more. In the heat imidization method, the treatment is preferably performed under an inert atmosphere such as a nitrogen atmosphere or a vacuum to prevent oxidation deterioration of the resin. With this treatment, volatile components remaining in the resin can be removed completely.

When reacting the diamine with the tetracarboxylic dianhydride, especially when a diamine having a butadiene-acrylonitrile copolymer skeleton is used, the reaction is preferably performed at a temperature of 100° C. or more. With this operation, gelation can be prevented.

In the adhesive layers 30 and 32, a thermosetting catalyst may be used as a constituting material of the adhesive layers 30 and 32 as necessary. The compounding ratio is preferably in a range of 0.01 to 5 parts by weight, more preferably in a range of 0.05 to 3 parts by weight, and especially preferably in a range of 0.1 to 1 part by weight to 100 parts by weight of the organic component. By making the compounding ratio 0.01 parts by weight or more, good adhering strength after thermal curing can be achieved. On the other hand, by making the compounding ratio 5 parts by weight or less, a decrease of storability can be suppressed.

The thermosetting catalyst is not especially limited, and examples thereof include an imidazole compound, a triphenylphosphine compound, an amine compound, a triphenylborane compound, and a trihalogenborane compound. These can be used alone or two types or more can be used together.

Examples of the imidazole compound include 2-methylimidazole (trade name; 2MZ), 2-undecylimidazole (trade name: C11Z), 2-heptadecylimidazole (trade name: C17Z), 1,2-dimethylimidazole (trade name: 1.2DMZ), 2-ethyl-4-methylimidazole (trade name: 2E4MZ), 2-phenylimidazole (trade name: 2PZ), 2-phenyl-4-methylimidazole (trade name: 2P4MZ), 1-benzyl-2-methylimidazole (trade name: 1B2MZ), 1-benzyl-2-phenylimidazole (trade name: 1B2PZ), 1-cyanoethyl-2-methylimidazole (trade name: 2MZ-CN), 1-cyanoethyl-2-undecylimidazole (trade name: C11Z-CN), 1-cyanoethyl-2-phenylimidazolium trimellitate (trade name: 2PZCNS-PW), 2,4-diamino-6-[2′-methylimidazolyl-(1′)]-ethyl-s-triazine (trade name: 2MZ-A), 2,4-diamino-6-[2′-undecylimidazolyl-(1′)]-ethyl-s-triazine (trade name: C11Z-A), 2,4-diamino-6-[2′-ethyl-4′-methylimidazolyl-(1′)]-ethyl-s-triazine (trade name: 2E4MZ-A), 2,4-diamino-6-[2′-methylimidazolyl-(1′)]-ethyl-s-triazineisocyanuric acid adduct (trade name: 2MA-OK), 2-phenyl-4,5-dihydroxymethylimidazole (trade name: 2PHZ-PW), and 2-phenyl-4-methyl-5-hydroxymethylimidazole (trade name: 2P4 MHZ-PW) (all are manufactured by Shikoku Chemicals Corporation).

The a triphenylphosphine compound is not particularly limited and includes, for example, triorganophosphines such as triphenylphosphine, tributylphosphine, tri(p-methylphenyl)phosphine, tri(nonylphenyl)phosphine and diphenyltolylphosphine, tetraphenylphosphonium bromide (TPP-PB), methyltriphenylphosphonium (trade name; TPP-MB), methyltriphenylphosphonium chloride (trade name; TPP-MC), methoxymethyltriphenylphosphonium (trade name; TPP-MOC) and benzyltriphenylphosphonium chloride (trade name; TPP-ZC) (all of which are manufactured by HOKKO CHEMICAL INDUSTRY CO., LTD.). The triphenylphosphine compound is preferably substantially insoluble in the epoxy resin. When the thermosetting catalyst is insoluble in the epoxy resin, it is possible to suppress thermal setting from excessively proceeding. The thermosetting catalyst which has a triphenylphosphine structure and also substantially exhibits insolubility in the epoxy resin includes, for example, methyltriphenylphosphonium (trade name; TPP-MB). The “insolubility” means that the thermosetting catalyst composed of the triphenylphosphine compound is insoluble in a solvent composed of an epoxy resin, and more specifically means that 10% by weight or more of the thermosetting catalyst does not dissolve at the temperature within a range from 10 to 40° C.

The triphenylborane compound is not particularly limited and further includes, for example, tri(p-methylphenyl)phosphine. The triphenylborane compound includes those having also a triphenylphosphine structure. The compound having a triphenylphosphine structure and a triphenylborane structure is not particularly limited and includes tetraphenylphosphonium tetraphenylborate (trade name; TPP-K), tetraphenylphosphonium tetra-p-triborate (trade name; TPP-MK), benzyltriphenylphosphonium tetraphenylborate (trade name; TPP-ZK) and triphenylphosphine triphenylborane (trade name; TPP-S) (all of which are manufactured by HOKKO CHEMICAL INDUSTRY CO., LTD.).

The amine compound is not particularly limited and includes, for example, monoethanolamine trifluoroborate (manufactured by Stella Chemifa Corporation) and dicyandiamide (manufactured by NACALAI TESQUE, INC.).

The trihalogenborane compound is not especially limited, and examples thereof include trichloroborane.

When performing crosslinking on the adhesive layers 30 and 32 to some extent in advance, a polyfunctional compound that reacts with a functional group at the end of the molecular chain of the polymer can be added as a crosslinking agent at production. With this addition, the adhesion characteristic under a high temperature can be improved, and heat resistance can be improved.

The crosslinking agent may be one known in the prior art. Particularly preferable are polyisocyanate compounds, such as tolylene diisocyanate, diphenylmethane diisocyanate, p-phenylene diisocyanate, 1,5-naphthalene diisocyanate, and adducts of polyhydric alcohol and diisocyanate. The amount of the crosslinking agent to be added is preferably set to 0.05 to 7 parts by weight for 100 parts by weight of the above-mentioned polymer. If the amount of the crosslinking agent to be added is more than 7 parts by weight, the adhesive force is unfavorably lowered. On the other hand, if the adding amount is less than 0.05 part by weight, the cohesive force is unfavorably insufficient. A different polyfunctional compound, such as an epoxy resin, together with the polyisocyanate compound may be incorporated if necessary.

A filler can be appropriately compounded in the adhesive layers 30 and 32 according to the usage. The compounding of a filler enables the provision of electric conductivity, improvement of thermal conductivity, and adjustment of modulus of elasticity. Examples of the filler include inorganic fillers and organic fillers. An inorganic filler is preferable from the viewpoint of characteristics such as improvement of the handling property, improvement of thermal conductivity, adjustment of melt viscosity, and provision of a thixotropic property. The inorganic filler is not especially limited, and examples thereof include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whisker, boron nitride, crystalline silica, and amorphous silica. These can be used alone or two types or more can be used together. From the viewpoint of improvement of thermal conductivity, aluminum oxide, aluminum nitride, boron nitride, crystalline silica, and amorphous silica are preferable. From the viewpoint of a good balance of the characteristics, crystalline silica and amorphous silica are preferable. Further, a conductive substance (conductive filler) may be used as an inorganic filler for the provision of electric conductivity and improvement of thermal conductivity. Examples of the conductive filler include a metal powder in which silver, aluminum, gold, copper, nickel, or a conductive alloy is made into a sphere, a needle, or a flake; a metal oxide of alumina, and the like, amorphous carbon black, and graphite.

The average particle size of the filler can be 0.005 to 10 μm. By making the average particle size of the filler 0.005 μm or more, a good wetting property to the adherend and good tackiness can be obtained. By making the average particle diameter 10 μm or less, the effect of the filler that is added to give each of the above-described characteristics can be made sufficient and heat resistance can be secured. The average particle size of the filler is a value obtained with, for example, a light intensity type particle size distribution meter (device name: LA-910 manufactured by HORIBA, Ltd.).

Other additives can be compounded in the adhesive layers 30 and 32 besides the filler as necessary. Examples of other additives include a flame retardant, a silane coupling agent, and an ion trap agent. Examples of the flame retardant include antimony trioxide, antimony pentoxide, and a brominated epoxy resin. These can be used alone or two types or more can be used together. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These compounds can be used alone or two types or more can be used together. Examples of the ion trap agent include hydrotalcites and bismuth hydroxide. These can be used alone or two types or more can be used together.

The thickness of the die bond films 40 and 41 (the total thickness including the electromagnetic wave shielding layer and the adhesive layer) is not especially limited. The thickness can be selected from a range of 1 to 10,000 μm for example, preferably 2 to 900 μm, and more preferably 3 to 800 μm.

The thickness of the adhesive layers 30 and 32 is not especially limited. The thickness can be selected so that the thickness of the die bond films 40 and 41 is in the above-described range and is, for example, 1 to 200 μm, preferably 2 to 150 μm, and more preferably 3 to 100 μm.

The die bond film according to the present embodiment can be used as a dicing die bond film by laminating on the dicing film. The dicing film is not especially limited, and a dicing film in which a pressure-sensitive adhesive layer is laminated on a substrate can be adopted. In the following, the dicing die bond film in which the die bond film according to the above-described embodiment is laminated on a dicing film is explained.

### (Dicing Die Bond Film)

FIG. 3 is a sectional schematic drawing showing one example of a dicing die bond film in which the die bond film shown in FIG. 2 is laminated. FIG. 4 is a sectional schematic drawing showing one example of another dicing die bond film in which the die bond film shown in FIG. 2 is laminated.

As shown in FIG. 3, a dicing die bond film 10 has a configuration in which the die bond film 41 is laminated onto a dicing film 11. The dicing film 11 is configured by laminating a pressure-sensitive adhesive layer 2 on a substrate 1, and the die bond film 41 is provided on the pressure-sensitive adhesive layer 2. The present invention may also have a configuration in which a die bond film 41′ is formed only on a workpiece pasting portion as in a dicing die bond film 12 shown in FIG. 4.

An ultraviolet-ray transmitting substrate can be used as the substrate 1, and the substrate 1 serves as a base body for strength of the dicing die bond films 10 and 12. Examples thereof include polyolefin such as low-density polyethylene, straight chain polyethylene, intermediate-density polyethylene, high-density polyethylene, very low-density polyethylene, random copolymer polypropylene, block copolymer polypropylene, homopolypropylene, polybutene, and polymethylpentene; an ethylene-vinylacetate copolymer; an ionomer resin; an ethylene(meth)acrylic acid copolymer; an ethylene(meth)acrylic acid ester (random or alternating) copolymer; an ethylene-butene copolymer; an ethylene-hexene copolymer; polyurethane; polyester such as polyethyleneterephthalate and polyethylenenaphthalate; polycarbonate; polyetheretherketone; polyimide; polyetherimide; polyamide; whole aromatic polyamides; polyphenylsulfide; aramid (paper); glass; glass cloth; a fluorine resin; polyvinyl chloride; polyvinylidene chloride; a cellulose resin; a silicone resin; metal (foil); and paper.

Further, the material of the base 1 includes a polymer such as a cross-linked body of the above resins. The above plastic film may be also used unstreched, or may be also used on which a monoaxial or a biaxial stretching treatment is performed depending on necessity. According to resin sheets in which heat shrinkable properties are given by the stretching treatment, etc., the adhesive area of the pressure-sensitive adhesive layer 2 and the die bond films 41 and 41′ are reduced by thermally shrinking the base 1 after dicing, and the recovery of the semiconductor chips (a semiconductor element) can be facilitated.

A known surface treatment such as a chemical or physical treatment such as a chromate treatment, ozone exposure, flame exposure, high voltage electric exposure, and an ionized ultraviolet treatment, and a coating treatment by an undercoating agent (for example, a tacky substance described later) can be performed on the surface of the base 1 in order to improve adhesiveness, holding properties, etc. with the adjacent layer.

The thickness of the substrate 1 can be appropriately determined without any special limitation. The thickness is generally about 5 to 200 μm.

The pressure-sensitive adhesive that is used for forming the pressure-sensitive adhesive layer 2 is not especially limited, and general pressure-sensitive adhesives such as an acrylic pressure-sensitive adhesive and a rubber pressure-sensitive adhesive can be used, for example. The pressure-sensitive adhesive is preferably an acrylic pressure-sensitive adhesive containing an acrylic polymer as a base polymer in view of clean washing of electronic components such as a semiconductor wafer and glass, which are easily damaged by contamination, with ultrapure water or an organic solvent such as alcohol.

Specific examples of the acryl polymers include an acryl polymer in which acrylate is used as a main monomer component. Examples of the acrylate include alkyl acrylate (for example, a straight chain or branched chain alkyl ester having 1 to 30 carbon atoms, and particularly 4 to 18 carbon atoms in the alkyl group such as methylester, ethylester, propylester, isopropylester, butylester, isobutylester, sec-butylester, t-butylester, pentylester, isopentylester, hexylester, heptylester, octylester, 2-ethylhexylester, isooctylester, nonylester, decylester, isodecylester, undecylester, dodecylester, tridecylester, tetradecylester, hexadecylester, octadecylester, and eicosylester) and cycloalkyl acrylate (for example, cyclopentylester, cyclohexylester, etc.). These monomers may be used alone or two or more types may be used in combination. All of the words including “(meth)” in connection with the present invention have an equivalent meaning.

The acrylic polymer may optionally contain a unit corresponding to a different monomer component copolymerizable with the above-mentioned alkyl ester of (meth)acrylic acid or cycloalkyl ester thereof in order to improve the cohesive force, heat resistance or some other property of the polymer. Examples of such a monomer component include carboxyl-containing monomers such as acrylic acid, methacrylic acid, carboxyethyl (meth)acrylate, carboxypentyl(meth)acrylate, itaconic acid, maleic acid, fumaric acid, and crotonic acid; acid anhydride monomers such as maleic anhydride, and itaconic anhydride; hydroxyl-containing monomers such as 2-hydroxyethyl (meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl (meth)acrylate, 12-hydroxylauryl(meth)acrylate, and (4-hydroxylmethylcyclohexyl)methyl(meth)acrylate; sulfonic acid group containing monomers such as styrenesulfonic acid, allylsulfonic acid, 2-(meth)acrylamide-2-methylpropanesulfonic acid, (meth) acrylamidepropanesulfonic acid, sulfopropyl (meth)acrylate, and (meth)acryloyloxynaphthalenesulfonic acid; phosphoric acid group containing monomers such as 2-hydroxyethylacryloyl phosphate; acrylamide; and acrylonitrile. These copolymerizable monomer components may be used alone or in combination of two or more thereof. The amount of the copolymerizable monomer(s) to be used is preferably 40% or less by weight of all the monomer components.

For crosslinking, the acrylic polymer can also contain multifunctional monomers if necessary as the copolymerizable monomer component. Such multifunctional monomers include hexane diol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylol propane tri(meth)acrylate, pentaerythritol tri(meth)acrylate, dipentaerythritol hexa(meth)acrylate, epoxy(meth)acrylate, polyester (meth)acrylate, urethane (meth)acrylate etc. These multifunctional monomers can also be used as a mixture of one or more thereof. From the viewpoint of adhesiveness etc., the use amount of the multifunctional monomer is preferably 30 wt % or less based on the whole monomer components.

Preparation of the Above Acryl Polymer can be Performed by applying an appropriate manner such as a solution polymerization manner, an emulsion polymerization manner, a bulk polymerization manner, and a suspension polymerization manner to a mixture of one or two or more kinds of component monomers for example. Since the pressure-sensitive adhesive layer preferably has a composition in which the content of low molecular weight materials is suppressed from the viewpoint of prevention of wafer contamination, and since those in which an acryl polymer having a weight average molecular weight of 300000 or more, particularly 400000 to 3000000 is as a main component are preferable from such viewpoint, the pressure-sensitive adhesive can be made to be an appropriate cross-linking type with an internal cross-linking manner, an external cross-linking manner, etc.

To increase the number-average molecular weight of the base polymer such as acrylic polymer etc., an external crosslinking agent can be suitably adopted in the pressure-sensitive adhesive. The external crosslinking method is specifically a reaction method that involves adding and reacting a crosslinking agent such as a polyisocyanate compound, epoxy compound, aziridine compound, melamine crosslinking agent, urea resin, anhydrous compound, polyamine, carboxyl group-containing polymer. When the external crosslinking agent is used, the amount of the crosslinking agent to be used is determined suitably depending on balance with the base polymer to be crosslinked and applications thereof as the pressure-sensitive adhesive. Generally, the crosslinking agent is preferably incorporated in an amount of about 5 parts by weight or less based on 100 parts by weight of the base polymer.

The lower limit of the crosslinking agent is preferably 0.1 parts by weight or more. The pressure-sensitive adhesive may be blended not only with the components described above but also with a wide variety of conventionally known additives such as a tackifier, and aging inhibitor, if necessary.

The pressure-sensitive adhesive layer 2 can be formed from a radiation curing type pressure-sensitive adhesive. The adhesive power of the radiation curing type pressure-sensitive adhesive can be easily decreased by increasing the degree of crosslinking by irradiation with radiation such as an ultraviolet ray, and a difference in the adhesive power of one portion 2a from a different portion 2b can be provided by irradiating only the portion 2a that corresponds to the workpiece pasting portion of the pressure-sensitive adhesive layer 2 shown in FIG. 4.

The portion 2a in which the adhesive power is remarkably decreased can be easily formed by curing the radiation curing type pressure-sensitive adhesive layer 2 in conformity with the die bond film 41′ shown in FIG. 4. Because the die bond film 41′ is pasted to the portion 2a that is cured and has decreased adhesive power, the interface between the portion 2a of the pressure-sensitive adhesive layer 2 and the die bond film 41′ has a property of easily peeling during pickup. On the other hand, the portion that is not irradiated with radiation has a sufficient adhesive power, and forms the portion 2b.

As described above, the portion 2b formed by an uncured radiation curing type pressure-sensitive adhesive is adhered to the die bond film 41, and holding power during dicing can be secured in the pressure-sensitive adhesive layer 2 of the dicing die bond film 10 shown in FIG. 3. In such a manner, the radiation curing type pressure-sensitive adhesive can support the die bond film 41 for fixing a chip-shaped workpiece such as a semiconductor chip to an adherend such as a substrate with a good balance between adhesion and peeling. In the pressure-sensitive adhesive layer 2 of the dicing die bond film 11 shown in FIG. 4, the portion 2b can fix a wafer ring.

A radiation curing type pressure-sensitive adhesive having an radiation curing type functional group such as a carbon-carbon double bond and exhibiting adherability can be used without special limitation. An example of the radiation curing type pressure-sensitive adhesive is an adding type radiation curing type pressure-sensitive adhesive in which radiation curing type monomer and oligomer components are compounded into a general pressure-sensitive adhesive such as an acrylic pressure-sensitive adhesive or a rubber pressure-sensitive adhesive.

Examples of the radiation curing type monomer component to be compounded include such as an urethane oligomer, urethane(meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butane dioldi(meth)acrylate. Further, the radiation curing type oligomer component includes various types of oligomers such as an urethane based, a polyether based, a polyester based, a polycarbonate based, and a polybutadiene based oligomer, and its molecular weight is appropriately in a range of about 100 to 30,000. The compounding amount of the radiation curing type monomer component and the oligomer component can be appropriately determined to an amount in which the adhesive strength of the pressure-sensitive adhesive layer can be decreased depending on the type of the pressure-sensitive adhesive layer. Generally, it is for example 5 to 500 parts by weight, and preferably about 40 to 150 parts by weight based on 100 parts by weight of the base polymer such as an acryl polymer constituting the pressure sensitive adhesive.

Further, besides the added type radiation curing type pressure sensitive adhesive described above, the radiation curing type pressure sensitive adhesive includes an internal radiation curing type pressure sensitive adhesive using an acryl polymer having a radical reactive carbon-carbon double bond in the polymer side chain, in the main chain, or at the end of the main chain as the base polymer. The internal radiation curing type pressure sensitive adhesives of an internally provided type are preferable because they do not have to contain the oligomer component, etc. that is a low molecular weight component, or most of them do not contain, they can form a pressure-sensitive adhesive layer having a stable layer structure without migrating the oligomer component, etc. in the pressure sensitive adhesive over time.

The above-mentioned base polymer, which has a carbon-carbon double bond, may be any polymer that has a carbon-carbon double bond and further has viscosity. As such a base polymer, a polymer having an acrylic polymer as a basic skeleton is preferable. Examples of the basic skeleton of the acrylic polymer include the acrylic polymers exemplified above.

The method for introducing a carbon-carbon double bond into any one of the above-mentioned acrylic polymers is not particularly limited, and may be selected from various methods. The introduction of the carbon-carbon double bond into a side chain of the polymer is easier in molecule design. The method is, for example, a method of copolymerizing a monomer having a functional group with an acrylic polymer, and then causing the resultant to condensation-react or addition-react with a compound having a functional group reactive with the above-mentioned functional group and a carbon-carbon double bond while keeping the ultraviolet ray curability of the carbon-carbon double bond.

Examples of the combination of these functional groups include a carboxylic acid group and an epoxy group; a carboxylic acid group and an aziridine group; and a hydroxyl group and an isocyanate group. Of these combinations, the combination of a hydroxyl group and an isocyanate group is preferable from the viewpoint of the easiness of reaction tracing. If the above-mentioned acrylic polymer, which has a carbon-carbon double bond, can be produced by the combination of these functional groups, each of the functional groups may be present on any one of the acrylic polymer and the above-mentioned compound. It is preferable for the above-mentioned preferable combination that the acrylic polymer has the hydroxyl group and the above-mentioned compound has the isocyanate group. Examples of the isocyanate compound in this case, which has a carbon-carbon double bond, include methacryloyl isocyanate, 2-methacryloyloxyethyl isocyanate, and m-isopropenyl-α,α-dimethylbenzyl isocyanate. The used acrylic polymer may be an acrylic polymer copolymerized with anyone of the hydroxyl-containing monomers exemplified above, or an ether compound such as 2-hydroxyethyl vinyl ether, 4-hydroxybutyl vinyl ether or diethylene glycol monovinyl ether.

The intrinsic type radiation curing type adhesive may be made only of the above-mentioned base polymer (in particular, the acrylic polymer), which has a carbon-carbon double bond. However, the above-mentioned radiation curing type monomer component or oligomer component may be incorporated into the base polymer to such an extent that properties of the adhesive are not deteriorated. The amount of the radiation curing type oligomer component or the like is usually 30 parts or less by weight, preferably from 0 to 10 parts by weight for 100 parts by weight of the base polymer.

In the case that the radiation curing type adhesive is cured with ultraviolet rays or the like, a photopolymerization initiator is incorporated into the adhesive. Examples of the photopolymerization initiator include α-ketol compounds such as 4-(2-hydroxyethoxy)phenyl(2-hydroxy-2-propyl)ketone, α-hydroxy-α,α′-dimethylacetophenone, 2-methyl-2-hydroxypropiophenone, and 1-hydroxycyclohexyl phenyl ketone; acetophenone compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether compounds such as benzoin ethyl ether, benzoin isopropyl ether, and anisoin methyl ether; ketal compounds such as benzyl dimethyl ketal; aromatic sulfonyl chloride compounds such as 2-naphthalenesulfonyl chloride; optically active oxime compounds such as 1-phenone-1,1-propanedione-2-(o-ethoxycarbonyl)oxime; benzophenone compounds such as benzophenone, benzoylbenzoic acid, and 3,3′-dimethyl-4-methoxybenzophenone; thioxanthone compound such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; acylphosphonoxides; and acylphosphonates. The amount of the photopolymerization initiator to be blended is, for example, from about 0.05 to 20 parts by weight for 100 parts by weight of the acrylic polymer or the like which constitutes the adhesive as a base polymer.

Examples of the radiation curing type pressure-sensitive adhesive include a rubber pressure-sensitive adhesive and an acrylic pressure-sensitive adhesive, that are disclosed in Japanese Patent Application Laid-Open No. 60-196956, containing an addition-polymerizable compound having two or more unsaturated bonds, a photopolymerizable compound such as alkoxysilane having an epoxy group, and a photopolymerization initiator such as a carbonyl compound, an organic sulfur compound, a peroxide, an amine, or an onium salt compound.

A compound that is colored by irradiation with radiation can be added to the radiation curing type pressure-sensitive adhesive layer 2 as necessary. By adding a compound that is colored by irradiation with radiation to the pressure-sensitive adhesive layer 2, only the portion that is irradiated with radiation can be colored. That is, the portion 2a that corresponds to the workpiece pasting portion 3a shown in FIG. 3 can be colored. Therefore, whether the pressure-sensitive adhesive layer 2 is irradiated with radiation or not can be determined visually right away, the workpiece pasting portion 3a is easily recognized, and the workpiece can be easily pasted. When detecting a semiconductor element with a light sensor or the like, the detection accuracy improves, and no incorrect operation occurs during pickup of the semiconductor element.

The compound that colors by irradiation with an radiation is colorless or has a pale color before the irradiation with an radiation. However, it is colored by irradiation with an radiation. A preferred specific example of the compound is a leuco dye. Common leuco dyes such as triphenylmethane, fluoran, phenothiazine, auramine, and spiropyran can be preferably used. Specific examples thereof include 3-[N-(p-tolylamino)]-7-anilinofluoran, 3-[N-(p-tolyl)-N-methylamino]-7-anilinofluoran, 3-[N-(p-tolyl)-N-ethylamino]-7-anilinofluoran, 3-diethylamino-6-methyl-7-anilinofluoran, crystal violet lactone, 4,4′,4″-trisdimethylaminotriphenylmethanol, and 4,4′,4″-trisdimethylaminotriphenylmethane.

Examples of a developer that is preferably used with these leuco dyes include a prepolymer of a conventionally known phenolformalin resin, an aromatic carboxylic acid derivative, and an electron acceptor such as activated white earth, and various publicly known color developers can be used in combination for changing the color tone.

The compound that colors by irradiation with an radiation may be included in the radiation curing-type pressure-sensitive adhesive after it is dissolved in an organic solvent or the like, or may be included in the pressure-sensitive adhesive in the form of a fine powder. The ratio of use of this compound is 10% by weight or less, preferably 0.01 to 10% by weight, and more preferably 0.5 to 5% by weight in the pressure-sensitive adhesive layer 2. When the ratio of the compound exceeds 10% by weight, the radiation that is delivered to the pressure-sensitive adhesive layer 2 is absorbed into this compound too much, and therefore curing of the portion 2a of the pressure-sensitive adhesive layer 2 becomes insufficient and there is a case that the adhesive power does not decrease sufficiently. On the other hand, the ratio of the compound is preferably 0.01% by weight or more to color the compound sufficiently.

When forming the pressure-sensitive adhesive layer 2 with the radiation curing type adhesive, a portion of the pressure-sensitive adhesive layer 2 may be irradiated with radiation so that the adhesive power of the portion 2a in the pressure-sensitive adhesive layer 2 becomes smaller than that of the different portion 2b.

An example of the method of forming the portion 2a on the pressure-sensitive adhesive layer 2 is a method of forming the radiation curing type pressure-sensitive adhesive layer 2 on the support base 1 and then curing the portion 2a by partially irradiating with radiation. The partial irradiation with radiation can be performed through a photo mask with a pattern that corresponds to a portion 3b, or the like excluding the workpiece pasting portion 3a. Another example is a method of curing the portion 2a by irradiating with radiation in spots. The radiation curing type pressure-sensitive adhesive layer 2 can be formed by transferring the layer that is provided on a separator onto the support base 1. The partial curing with radiation can also be performed on the radiation curing type pressure-sensitive adhesive layer 2 that is provided on the separator.

When forming the pressure-sensitive adhesive layer 2 with the radiation curing type pressure-sensitive adhesive, the portion 2a in which the adhesive power is decreased can be formed by using the support base 1 in which the entire portion or one portion other than the portion that corresponds to the workpiece pasting portion 3a of at least one surface of the support base 1 is shielded from light, forming the radiation curing type pressure-sensitive adhesive layer 2, and curing a portion that corresponds to the workpiece pasting portion 3a by irradiating the support base 1 and the pressure-sensitive adhesive layer 2 with radiation. The shielding material that serves as a photo mask on the support film can be produced by printing, vapor deposition, or the like. According to such a manufacturing method, the dicing die bond film 10 can be efficiently manufactured.

When curing inhibition by oxygen occurs at irradiation with radiation, oxygen (air) is desirably shielded from the surface of the radiation curing type pressure-sensitive adhesive layer 2 by some method. Examples thereof include a method of covering the surface of the pressure-sensitive adhesive layer 2 with a separator and a method of performing irradiation with radiation such as an ultraviolet ray in a nitrogen gas atmosphere.

The thickness of the pressure-sensitive adhesive layer 2 is not especially limited. The thickness is preferably about 1 to 50 μm from the viewpoints of preventing chipping of a chip cut section, compatibility of fixing and holding of the adhesive layer, and the like. The thickness is preferably 2 to 30 μm and further preferably 5 to 25 μm.

The die bond films 41 and 41′ of the dicing die bond films 10 and 12 are preferably protected by a separator (not shown in the drawings). The separator has a function as a protective material that protects the die bond films 41 and 41′ until they are put into practical use. The separator can be used also as a support base when transferring the die bond films 41 and 41′ to the pressure-sensitive adhesive layer 2. The separator is peeled off when the workpiece is pasted onto the die bond films 41 and 41′ of the dicing die bond film. As the separator, polyethylene terephthalate (PET), polyethylene, polypropylene, and a plastic film and paper whose surface is coated with a peeling agent such as a fluorine peeling agent or a long chain alkylacrylate peeling agent can be used.

### (Method of Manufacturing Die Bond Film)

A method of manufacturing the die bond films 40 and 41 is explained. First, an adhesive composition solution that is a forming material of the adhesive layer 30 is produced. A filler, various additives, and the like may be compounded in the adhesive composition solution in addition to the adhesive composition as necessary.

The adhesive layer 30 is formed by forming a coating film by applying the adhesive composition solution onto a base separator to have a prescribed thickness and drying the coating film under a prescribed condition. The coating method is not especially limited. Examples thereof include roll coating, screen coating, and gravure coating. An example of the drying condition is a drying temperature of 70 to 160° C. and a drying time of 1 to 5 minutes.

Next, the electromagnetic wave shielding layer 31 is formed on the adhesive layer 30. The electromagnetic wave shielding layer 31 can be formed by a sputtering method, a vapor deposition method such as a CVD method or a vacuum vapor deposition method, a plating method, an immersion method, or a painting method using the above-described materials. The electromagnetic wave shielding layer 31 can be formed also by pressure-bonding the above-described material previously made into a film (a metal foil, for example) to the adhesive layer 30. By the above-described processes, the die bond film 40 can be obtained.

The die bond film 41 can be obtained by further forming the adhesive layer 32 on the electromagnetic wave shielding layer 31. A material (adhesive composition) for forming the adhesive layer 32 is applied onto a release paper to a prescribed thickness and a coating layer is formed under a prescribed condition. The die bond film 41 is formed by transferring this coating layer onto the electromagnetic wave shielding layer 31. The adhesive layer 32 can be formed also by applying the forming material directly onto the electromagnetic wave shielding layer 31 and then drying the material under a prescribed condition.

### (Method of Manufacturing Dicing Die Bond Film)

A method of manufacturing a dicing die bond film is explained using the dicing die bond film 10 as an example. First, the base 1 can be formed by a conventionally known film forming method. Examples of the film forming method include a calender film forming method, a casting method in an organic solvent, an inflation extrusion method in a closed system, a T die extrusion method, a co-extrusion method, and a dry laminating method.

Next, the pressure-sensitive adhesive layer 2 is formed by forming a coating film by applying the pressure-sensitive adhesive composition solution to the base 1 and then drying the coating film under a prescribed condition (performing crosslinking by heating as necessary). The coating method is not especially limited, and examples thereof include roll coating, screen coating, and gravure coating. The drying is performed under drying conditions of a drying temperature of 80 to 150° C. and a drying time of 0.5 to 5 minutes, for example. The pressure-sensitive adhesive layer 2 may also be formed by forming the coating film by applying the pressure-sensitive adhesive composition onto the separator and then drying the coating film under the above-described drying conditions. After that, the pressure-sensitive adhesive layer 2 is pasted onto the base 1 together with the separator. With this operation, the dicing film 11 is produced.

The adhesive layer 32 of the previously manufactured die bond film 41 and the pressure-sensitive adhesive layer 2 are pasted together so that these layers form a pasting surface. Pasting can be performed by pressure-bonding, for example. At this time, the lamination temperature is not especially limited. The temperature is preferably 30 to 50° C. and more preferably 35 to 45° C. The linear pressure is not especially limited. The pressure is preferably 0.1 to 20 kgf/cm, and more preferably 1 to 10 kgf/cm. Next, the dicing die bond film 10 according to the present embodiment can be obtained by peeling the base separator on the adhesive layer. The dicing die bond film 10 can also be obtained by directly forming the adhesive layer 30, the electromagnetic wave shielding layer 31, and the adhesive layer 32 sequentially on the pressure-sensitive adhesive layer 2. In this case, the method of forming the adhesive layer 30, the electromagnetic wave shielding layer 31, and the adhesive layer 32 may be the same as the method of manufacturing the above-described die bond film.

### (Method of Manufacturing Semiconductor Device)

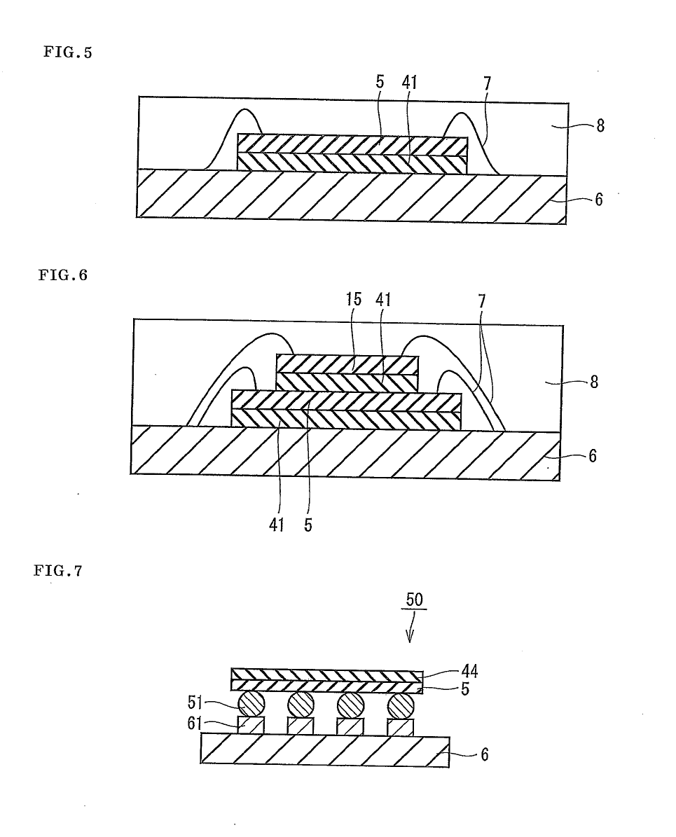

The separator that is optionally provided on the die bond films 41 and 41′ is properly peeled off and the dicing die bond films 10 and 12 of the present invention are used as follows. In the following, explanation is made using a case in which the dicing die bond film 10 is used as an example by referring to FIG. 5. FIG. 5 is a sectional schematic drawing showing an example in which a semiconductor chip is mounted interposing the die bond film in the dicing die bond film shown in FIG. 3.

First, a semiconductor wafer 4 is pressure-bonded onto the semiconductor wafer pasting portion 3a of the die bond film 41 in the dicing die bond film 10, and the resultant is fixed by adhering and holding (a pasting step). This step is performed while pressing the laminate with a pressing means such as a press roll. The pasting temperature at mounting is not especially limited. The temperature is preferably in a range of 20 to 80° C.

Next, dicing of the semiconductor wafer 4 is performed. With this operation, a semiconductor chip 5 is manufactured by cutting the semiconductor wafer 4 into an individual piece having a prescribed size. The dicing can be performed according to a normal method from the circuit surface side of the semiconductor wafer 4. A cutting method called full cut in which cutting is performed to the dicing die bond film 10, for example, can be adopted in this step. The dicing apparatus used in this step is not especially limited, and a conventionally known apparatus can be used. Because the semiconductor wafer is adhered and fixed to the dicing die bond film 10, chip cracks and chip fly can be suppressed and damages to the semiconductor wafer 4 can be suppressed. At this time, when the electromagnetic wave shielding layer 31 constituting the die bond film 41 is a vapor-deposited film that is formed by a vapor deposition method, sawdust is hardly generated in blade dicing, and contamination of the semiconductor chip can be prevented. In addition, damages to the blade can be suppressed.

Then, pickup of the semiconductor chip 5 is performed to peel off the semiconductor chip that is adhered and fixed to the dicing die bond film 10. The method of pickup is not especially limited and various conventionally known methods can be adopted. An example is a method of pushing up the individual semiconductor chip 5 with a needle from the dicing die bond film 10 side and picking up the semiconductor chip 5 that is pushed up with a pickup apparatus.

When the pressure-sensitive adhesive layer 2 is of ultraviolet-ray curing-type, pickup is performed after the pressure-sensitive adhesive layer 2 is irradiated with an ultraviolet ray. With this operation, the adhesive power of the pressure-sensitive adhesive layer 2 to the die bond film 41 decreases, and peeling of the semiconductor chip 5 becomes easy. As a result, pickup becomes possible without damaging the semiconductor chip 5. The conditions of ultraviolet ray irradiation such as the radiation intensity and the radiation time are not especially limited, and they may be set appropriately as necessary. The above-described light source can be used in the ultraviolet ray irradiation.

The semiconductor chip 5 that has been picked up is adhered and fixed to an adherend 6 interposing the die bond film 41 (die bonding). Examples of the adherend 6 include a lead frame, a TAB film, a substrate, and a semiconductor chip that is separately produced. The adherend 6 may be a deformation type adherend that can be easily deformed or a non-deformation type adherend that is difficult to be deformed such as a semiconductor wafer.

Conventionally known substrates can be used as the substrate. A metal lead frame such as a Cu lead frame or a 42 Alloy lead frame, or an organic substrate made of glass epoxy, BT (bismaleimide-triazine), or polyimide can be used as the lead frame. However, the present invention is not limited to these, and includes a circuit board that can be used by mounting the semiconductor element and electrically connecting to the semiconductor element.

Because the adhesive layers 30 and 32 are of thermosetting type, the heat resistance strength is improved by adhering and fixing the semiconductor chip 5 to the adherend 6 by thermal curing. The heating temperature is 80 to 200° C., preferably 100 to 175° C., and more preferably 100 to 140° C. The heating time is 0.1 to 24 hours, preferably 0.1 to 3 hours, and more preferably 0.2 to 1 hour. The semiconductor chip 5 that is adhered and fixed to a substrate or the like interposing the adhesive layers 30 and 32 can be used in a reflow step.

The shear adhering strength of the adhesive layers 30 and 32 to the semiconductor chip after thermal curing is preferably 0.2 MPa or more and 5 MPa or less under a condition of 17° C.

When the shear adhering strength of the adhesive layers 30 and 32 is 0.2 MPa or more, shear deformation hardly occurs at the adhering surface of the adhesive layers 30 and 32 and the semiconductor chip 5 or the adherend 6 due to the ultrasonic wave vibration and heating in this step. That is, the semiconductor element does not move much by the ultrasonic wave vibration during wire bonding, and accordingly, a decrease of the success rate of wire bonding can be prevented.

In the method of manufacturing a semiconductor device according to the present invention, wire bonding may be performed without the thermal curing step by heat treatment of the adhesive layers 30 and 32, the semiconductor chip 5 may be sealed with a sealing resin, and then after curing of the sealing resin may be performed. In this case, the shear adhering strength of the adhesive layers 30 and 32 during temporary fixing to the adherend 6 is preferably 0.2 MPa or more, and more preferably 0.2 to 10 MPa. When the shear adhering strength of the adhesive layers 30 and 32 during temporary fixing is at least 0.2 MPa or more, shear deformation hardly occurs at the adhering surface of the adhesive layers 30 and 32 and the semiconductor chip 5 or the adherend 6 due to the ultrasonic wave vibration and heating in this step even when the wire bonding step is performed without the heating step. That is, the semiconductor element does not move much by the ultrasonic wave vibration during wire bonding, and accordingly, a decrease of the success rate of wire bonding can be prevented.

The wire bonding is a step of electrically connecting the tip of a terminal part (inner lead) of the adherend 6 and electrode pads (not shown in the drawings) on the semiconductor chip 5 with a bonding wire 7 (refer to FIG. 5). Examples of the bonding wire 7 include a gold wire, an aluminum wire, and a copper wire. The temperature at wire bonding is 80 to 250° C. and preferably 80 to 220° C. The heating time is a few seconds to a few minutes. The wire bonding is performed by using vibration energy from an ultrasonic wave and pressure-bonding energy from the applied pressure while heating the wire to a temperature in the above-described temperature range. This step may be carried out without thermal curing of the adhesive layers 30 and 32.

The sealing step is a step of sealing the semiconductor chip 5 with a sealing resin 8 (refer to FIG. 5). This step is performed to protect the semiconductor chip 5 that is mounted on the adherend 6 and the bonding wire 7. This step is performed by molding the resin for sealing with a mold. An example of the sealing resin 8 is an epoxy resin. The heating temperature during resin sealing is normally 175° C. and sealing is performed for 60 to 90 seconds. However, the present invention is not limited to this, and curing can be performed at 165 to 185° C. for a few minutes. With this operation, the sealing resin is cured and the semiconductor chip 5 and the adherend 6 are fixed interposing the die bond film 41. That is, in the present invention, fixing by the die bond film 41 is possible in this step even when the post curing step that is described later is not performed, which can contribute to a reduction of the number of manufacturing steps and a reduction of the manufacturing time of the semiconductor device.

In the post curing step, the sealing resin 8 that is not cured sufficiently in the sealing step is completely cured. Even when the adhesive layers 30 and 32 are not completely thermally cured in the sealing step, complete thermal curing of the adhesive layers 30 and 32 together with the sealing resin 8 becomes possible in this step. The heating temperature in this step differs according to the type of sealing resin. The temperature is in a range of 165 to 185° C., and the heating time is about 0.5 to 8 hours. With this operation, a semiconductor device can be obtained in which the die bond film 41 (an adhesive film for a semiconductor device) is provided between the adherend 6 and the semiconductor chip 5.

As shown in FIG. 6, the die bond film 41 can be suitably used even when a plurality of the semiconductor chips are laminated and three dimensionally mounted. FIG. 6 is a sectional schematic drawing showing an example in which a semiconductor chip is three dimensionally mounted interposing the die bond film in the dicing die bond film shown in FIG. 3. In case of three dimensional mounting shown in FIG. 6, a piece of the die bond film 41 that is cut out to have the same size as the semiconductor chip is die bonded onto the adherend 6 and then the semiconductor chip 5 is die bonded interposing the die bond film 41 so that the wire bonding surface of the semiconductor chip 5 faces upward. A different die bond film 41 is pasted while avoiding the electrode pad part of the semiconductor chip 5. Further, a different semiconductor chip 15 is die bonded onto the different die bond film 41 so that the wire bonding surface faces upward.

Next, thermal curing of the die bond film 41 is performed, and then the wire bonding step is performed. With this operation, the semiconductor chip 5 and each electrode pad on the semiconductor chip 15, and the adherend 6 are electrically connected with the bonding wire 7.

Then, the sealing resin 8 is cured by performing the sealing step of sealing the semiconductor chip 5 and the like with the sealing resin 8. The post curing step may be performed after the sealing step. With the above operation, a semiconductor device can be obtained in which the die bond film 41 (an adhesive film for a semiconductor device) is provided between the semiconductor chip 5 and the different semiconductor chip 15.

Because the number of bonding wires 7 that connect the semiconductor chips 5 and 15 and the adherend 6 increases in the case of three dimensionally mounting the semiconductor chip, the time that is spent for the wire bonding step tends to be longer and the laminate tends to be exposed to a high temperature for a long time. However, progress of the thermal curing reaction can be suppressed using the die bond film 41 even when the laminate is exposed to a high temperature for a long time.

The 180 degree peeling strength between the dicing film 41 and the semiconductor wafer 3 (semiconductor chip 5) is preferably 0.5 N/10 mm or more, more preferably 1.0 N/10 mm or more, and further preferably 1.5 N/10 mm or more. By making the 180 degree peeling strength 0.5 N/10 mm or more, interlayer peeling becomes difficult to occur and the yield can be improved.

The 180 degree peeling strength can be measured as follows in accordance with JIS 20237. First, the adhesive layer is lined with a pressure-sensitive adhesive tape (BT-315 manufactured by Nitto Denko Corporation) and cut into a piece of 10×100 mm. Next, the cut adhesive layer is pasted to a semiconductor wafer. The pasting is performed by moving a roller of 2 kg back and forth on a hot plate of 50° C. After that, the resultant is left for 20 minutes under an atmosphere of normal temperature (25° C.), and a test piece is obtained. The 180 degree peeling force between the adhesive layer and the semiconductor wafer is measured using a tensile tester (AGS-J manufactured by Shimadzu Corporation).

The case is exemplified in which the adhesive film for a semiconductor device of the present invention is the die bond films 40 and 41 in the above-described embodiment. However, the adhesive film for a semiconductor device of the present invention may be a film for the backside of a flip-chip type semiconductor. The case is explained below in which the film for a semiconductor device of the present invention is a film for the backside of a flip-chip type semiconductor.

FIG. 7 is a sectional schematic drawing showing one example of a flip-chip type semiconductor device using a film for the backside of the flip-chip type semiconductor. As shown in FIG. 7, a film 44 for the backside of a flip-chip type semiconductor is formed on the backside of the semiconductor chip 5 in a flip-chip type semiconductor device 50. The backside of the semiconductor chip means the surface opposite to the surface where a circuit is formed. The composition and the manufacturing method of the film 44 for the backside of a flip-chip type semiconductor may be the same as those of the die bond film 40, for example. As shown in FIG. 7, the semiconductor chip 5 is fixed to the adherend 6 by a flip-chip bonding system (flip-chip mounting system). Specifically, the semiconductor chip 5 is fixed to the adherend 6 by a normal method in a state where the circuit surface (also referred to as the surface, a circuit pattern forming surface, or an electrode forming surface) of the semiconductor chip 5 is opposing the adherend 6. For example, the semiconductor chip 5 is fixed to the adherend 6 by contacting a bump 51 that is formed on the circuit surface side of the semiconductor chip 5 to a conductive material 61 such as solder for connecting that is attached to connection pads of the adherend 6 while pressing and melting the conductive material. The pasting of the film 44 for the backside of a flip-chip type semiconductor to the backside of the semiconductor chip 5 may be performed after the flip-chip connection of the semiconductor chip 5 onto the adherend 6 or before the flip-chip connection of the semiconductor chip 5 onto the adherend 6 after dicing of the semiconductor wafer 4. The flip-chip type semiconductor device 50 is a semiconductor device in which the film 44 for the backside of a flip-chip type semiconductor (adhesive film for a semiconductor device) is provided onto the semiconductor chip 5.

The 180 degree peeling strength between the film 44 for the backside of a flip-chip type semiconductor and the semiconductor chip 5 is preferably 0.5 N/10 mm or more, more preferably 1.0 N/10 mm or more, and further preferably 1.5N/10 mm or more. By making the 180 degree peeling strength 0.5 N/10 mm or more, interlayer peeling becomes difficult to occur and the yield can be improved.

The 180 degree peeling strength can be measured as follows in accordance with JIS 20237. First, the adhesive layer is lined with a pressure-sensitive adhesive tape (BT-315 manufactured by Nitto Denko Corporation) and cut into a piece of 10×100 mm. Next, the cut adhesive layer is pasted to a semiconductor wafer. The pasting is performed by moving a roller of 2 kg back and forth on a hot plate of 50° C. After that, the resultant is left for 20 minutes under an atmosphere of normal temperature (25° C.), and a test piece is obtained. The 180 degree peeling force between the adhesive layer and the semiconductor wafer is measured using a tensile tester (AGS-J manufactured by Shimadzu Corporation).

The case in which an electromagnetic wave shielding layer 31 is a single layer was explained in the above-described embodiment. However, the electromagnetic wave shielding layer is not limited to a single layer and it may be two or more layers in the present invention. When the electromagnetic wave shielding layer has two or more layers, the layer configuration is not especially limited. For example, a plurality of electromagnetic wave shielding layers may be laminated without other layers interposed therebetween, or a plurality of electromagnetic wave shielding layers may be laminated with other layers (adhesive layers for example) interposed therebetween. When the electromagnetic wave shielding layer has two or more layers, the electromagnetic wave can be attenuated by one electromagnetic wave shielding layer first and further attenuated by other electromagnetic wave shielding layers.

### EXAMPLES

Below, preferred examples of the present invention are explained in detail. However, materials, addition amounts, and the like described in these examples are not intended to limit the scope of the present invention, and are only examples for explanation as long as there is no description of limitation in particular. Further, “part” means “parts by weight.”

### Example 1

### Production of Adhesive Layer A

Adhesive composition solutions having a concentration of 23.6% by weight were obtained by dissolving the following (a) to (f) in methylethylketone.

(a) 100 parts of an acrylic ester polymer having ethyl acrylate-methyl methacrylate as a main component (Paracron W-197CM manufactured by Negami Chemical Industries Co., Ltd.)

(b) 242 parts of an epoxy resin 1 (Epicoat 1004 manufactured by Japan Epoxy Resin Co., Ltd.)

(c) 220 parts of an epoxy resin 2 (Epicoat 827 manufactured by Japan Epoxy Resin Co., Ltd.)

(d) 489 parts of a phenol resin (Milex XLC-4L manufactured by Mitsui Chemicals, Inc.)

(e) 660 parts of spherical silica (SO-25R manufactured by Admatechs Co., Ltd.)

(f) 3 parts of a thermosetting catalyst (C11-Z manufactured by Shikoku Chemicals Corporation)

An adhesive layer A having a thickness of 60 μm was produced by applying this adhesive composition solution onto a release-treated film (a release liner) made of polyethylene terephthalate and having a thickness of 50 μm subjected to a silicone releasing treatment and drying the solution at 130° C. for 2 minutes.

### Production of Adhesive Layer B

Adhesive composition solutions having a concentration of 23.6% by weight were obtained by dissolving the following (a) to (d) in methylethylketone.

(a) 100 parts of an acrylic ester polymer (SG-80H manufactured by Nagase ChemteX Corporation)

(b) 10 parts of an epoxy resin (HP-7200H manufactured by DIC Corporation)

(c) 10 parts of a phenol resin (Milex XLC-4L manufactured by Mitsui Chemicals, Inc.)

(d) 63 parts of spherical silica (SO-25R manufactured by Admatechs Co., Ltd.)

An adhesive layer B having a thickness of 10 μm was produced by applying this adhesive composition solution onto a release-treated film (a release liner) made of polyethylene terephthalate and having a thickness of 50 μm subjected to a silicone releasing treatment and drying the solution at 130° C. for 2 minutes.

### <Production of Adhesive Film for Semiconductor Device>

An adhesive film for a semiconductor device having a thickness of 90 μm was produced by pasting an aluminum foil manufactured by Toyo Aluminum. K.K. having a thickness of 20 μm between the adhesive layer A and the adhesive layer B under conditions of a temperature of 80° C., a pasting pressure of 0.3 MPa, and a pasting speed of 10 mm/sec. The aluminum foil has a function as an electromagnetic wave shielding layer.

### Example 2

### Production of Adhesive Film for Semiconductor Device

An adhesive film for a semiconductor device having a thickness of 108 μm was produced by pasting a SUS304 (stainless steel) foil having a thickness of 38 μm between the adhesive layer A and the adhesive layer B under conditions of a temperature of 80° C., a pasting pressure of 0.3 MPa, and a pasting speed of 10 mm/sec. The SUS304 foil has a function as an electromagnetic wave shielding layer.

### Example 3

### Production of Adhesive Film for Semiconductor Device

An aluminum layer having a thickness of 500 nm was formed on the adhesive layer A by a sputtering method using a sputtering machine (SH-550 manufactured by ULVAC, Inc.). The sputtering conditions were as follows.

### (Sputtering Conditions)

### Target: Aluminum

Discharge power: DC 600 W (Output density 3.4 W/cm²)
System pressure: 0.56 Pa
Ar flow rate: 40 sccm
Substrate temperature: not heated
Film forming rate: 20 nm/min

Then, an adhesive film for a semiconductor device having a thickness of 70.5 μm was produced by pasting the adhesive layer B onto an aluminum layer under conditions of a temperature of 80° C., a pasting pressure of 0.3 MPa, and a pasting speed of 10 mm/sec. The aluminum layer has a function as an electromagnetic wave shielding layer.

### Example 4

### Production of Adhesive Film for Semiconductor Device

An adhesive film for a semiconductor device having a thickness of 90 μm was produced by pasting a nickel foil having a thickness of 20 μm between the adhesive layer A and the adhesive layer B under conditions of a temperature of 80° C., a pasting pressure of 0.3 MPa, and a pasting speed of 10 mm/sec. The nickel foil has a function as an electromagnetic wave shielding layer.

### Example 5

### Production of Adhesive Film for Semiconductor Device

An adhesive film for a semiconductor device having a thickness of 82 μm was produced by pasting a copper foil having a thickness of 12 μm between the adhesive layer A and the adhesive layer B under conditions of a temperature of 80° C., a pasting pressure of 0.3 MPa, and a pasting speed of 10 mm/sec. The copper foil has a function as an electromagnetic wave shielding layer.

### Example 6

### Production of Adhesive Film for Semiconductor Device

A film was prepared having a PET (polyethylene terephthalate) film having a thickness of 50 μm on both sides and on which a finemet layer having a thickness of 18 μm was formed (FP-FT-5M manufactured by Hitachi Metals, Ltd., referred to as “a finemet film” in the following). The finemet layer is an amorphous thin zone that was formed by solidifying a high temperature melt liquid of a composition in which Si (silicon), B (boron), a small amount of Cu (copper), and Nb (niobium) were added into Fe as the main component by rapidly cooling at about 1,000,000° C./sec.

Then, an adhesive film for a semiconductor device having a thickness of 188 μm was produced by pasting the finemet film between the adhesive layer A and the adhesive layer B under conditions of a temperature of 80° C., a pasting pressure of 0.3 MPa, and a pasting speed of 10 mm/sec. At this time, the film was pasted so that the adhesive layer A and the PET film would face each other and the adhesive layer B and the finemet layer would face each other. The finemet layer has a function as an electromagnetic wave shielding layer.

### Comparative Example 1

The adhesive film for a semiconductor device according to this comparative example was produced by pasting the adhesive layer A and the adhesive layer B together in the same manner as in Example 1 except that the aluminum foil was not used.

### Comparative Example 2

### Production of Adhesive Film for Semiconductor Device

A film was prepared in which a ferrite layer having a thickness of 3 μm was formed on a PET film having a thickness of 38 μm. The ferrite layer according to Comparative Example 2 is a layer made of NiZn ferrite produced by a ferrite plating method.

Then, an adhesive film for a semiconductor device having a thickness of 111 μm was produced by pasting the ferrite film between the adhesive layer A and the adhesive layer B under conditions of a temperature of 80° C., a pasting pressure of 0.3 MPa, and a pasting speed of 10 mm/sec. At this time, the film was pasted so that the adhesive layer A and the PET film would face each other and the adhesive layer B and the ferrite layer would face each other.

<Measurement of Electromagnetic Wave Attenuation (dB)>

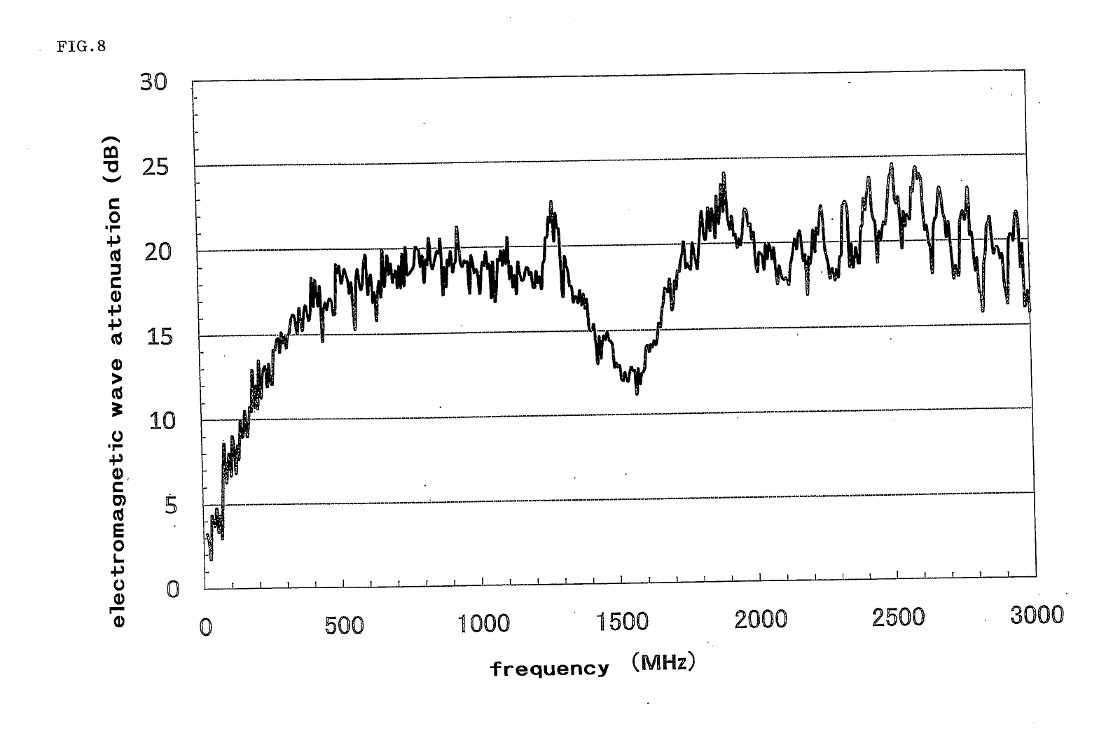

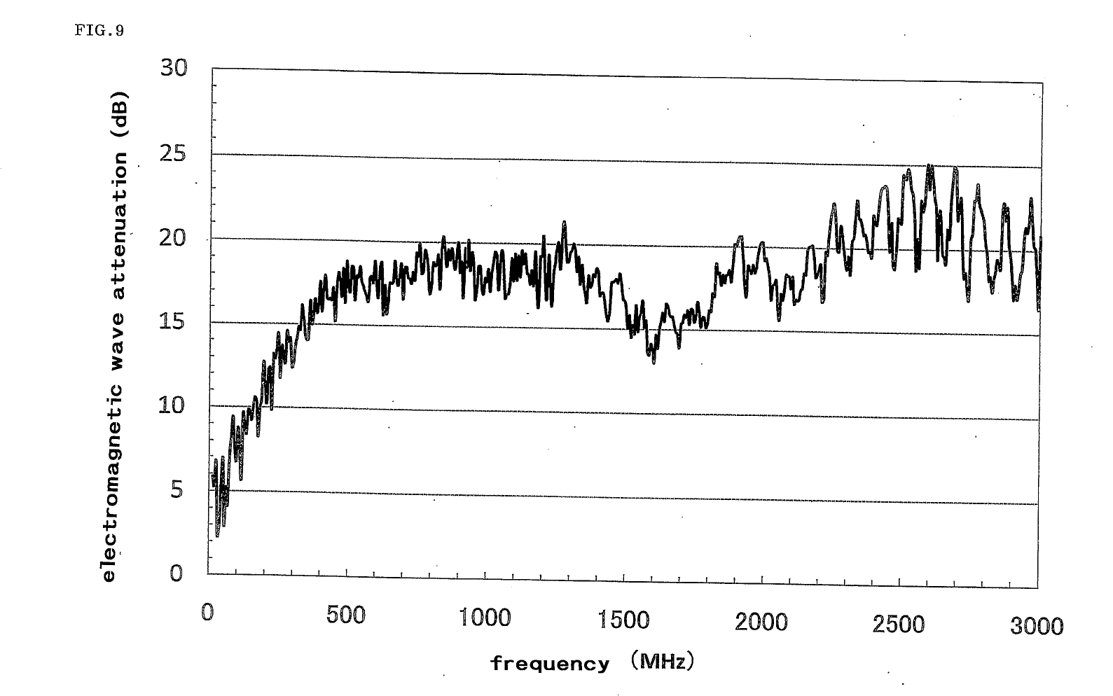

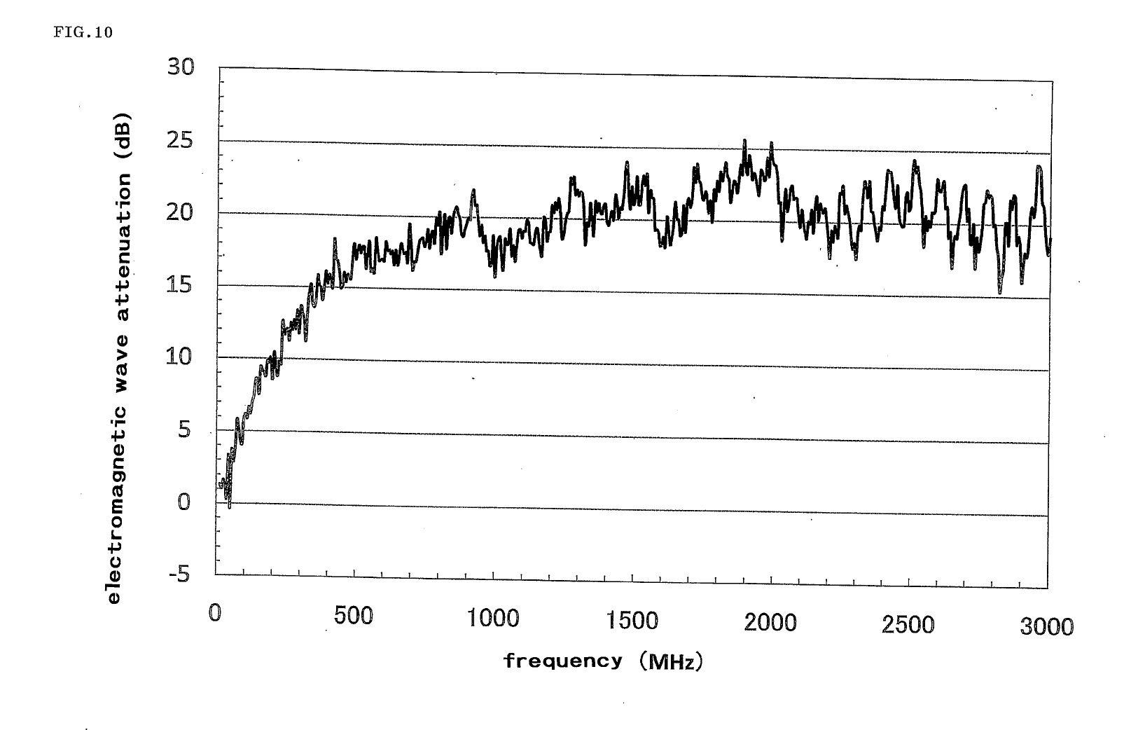

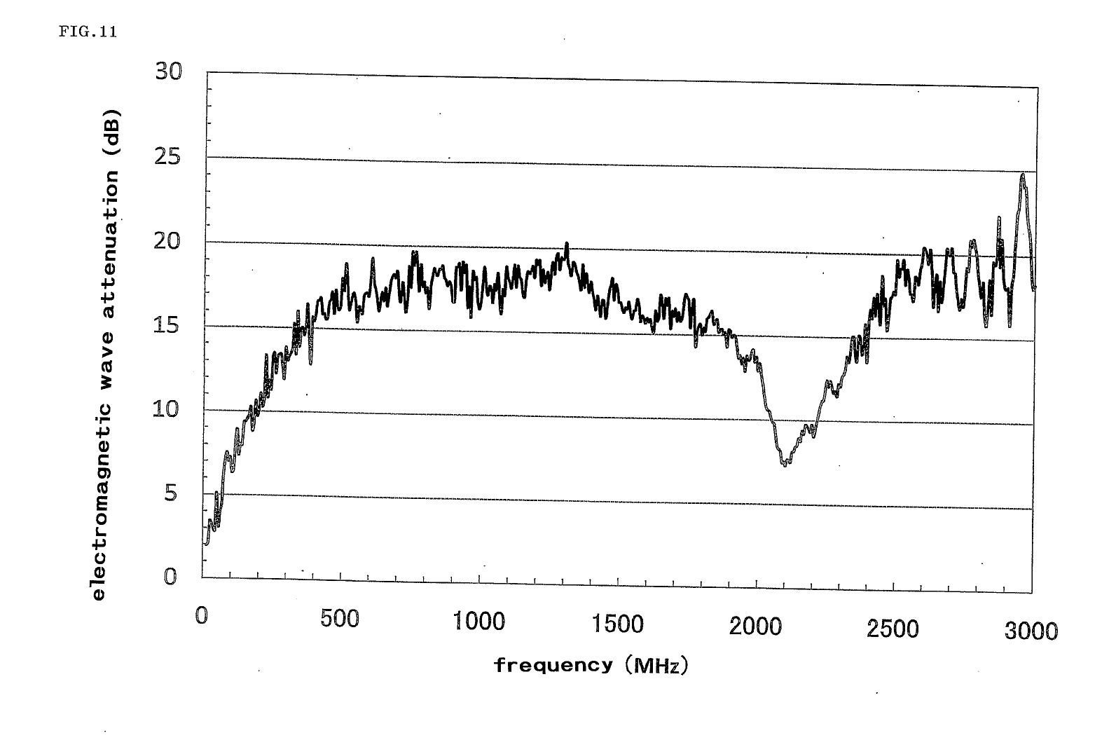

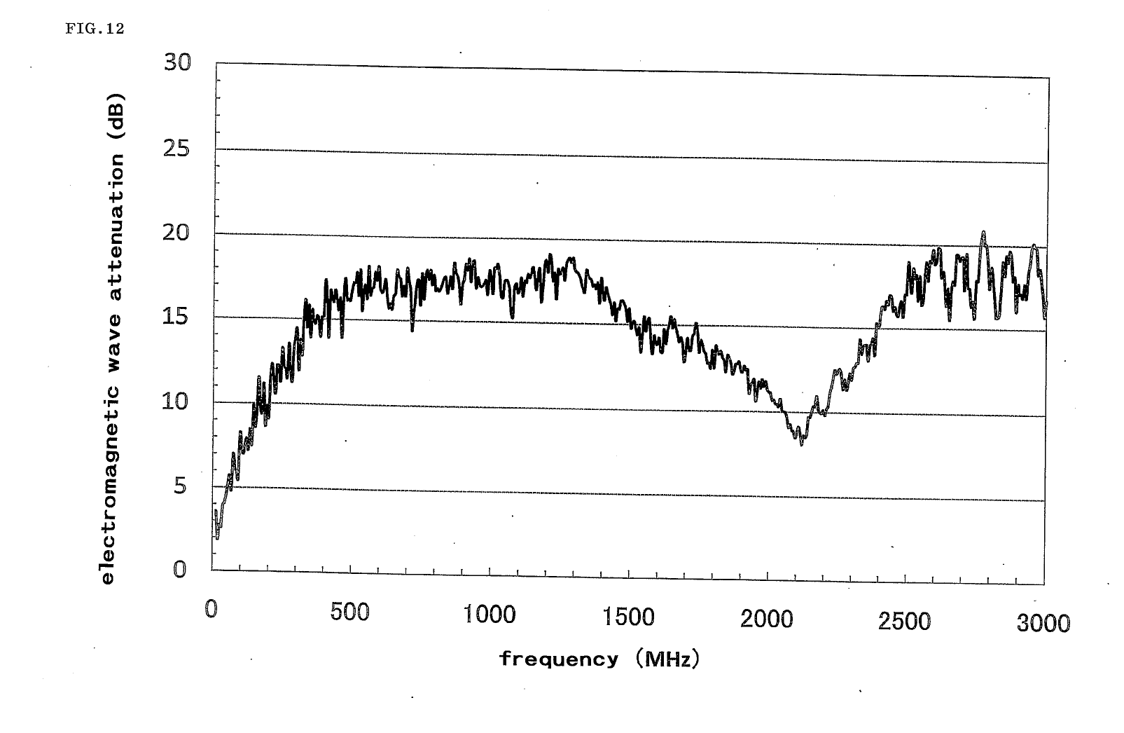

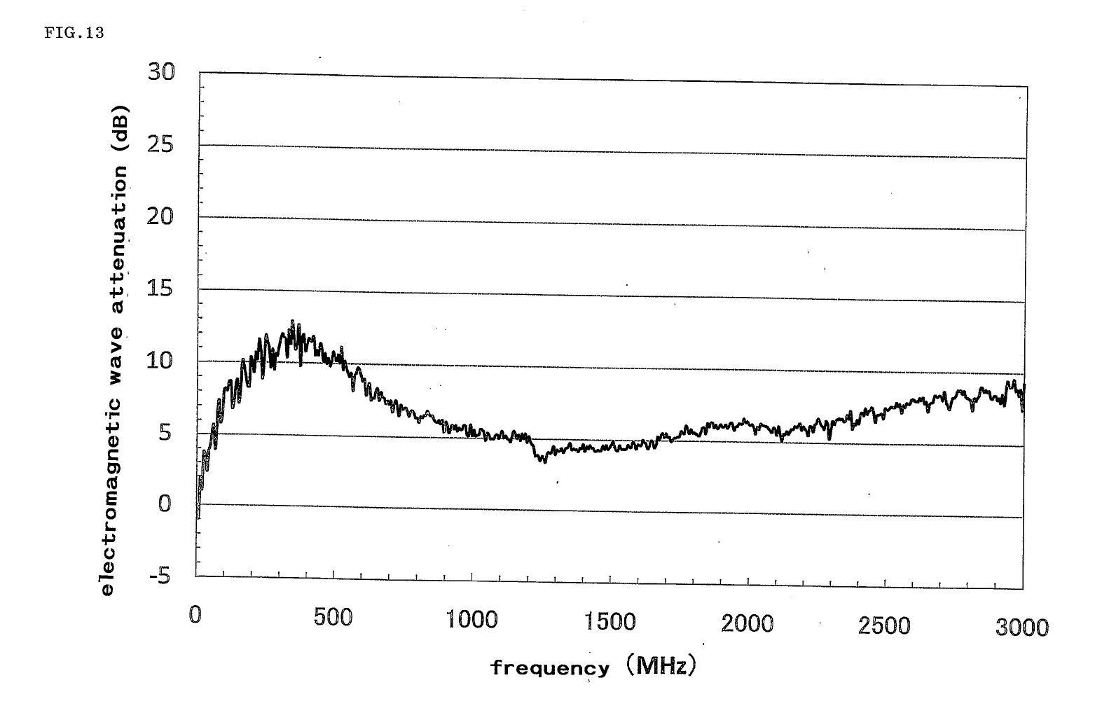

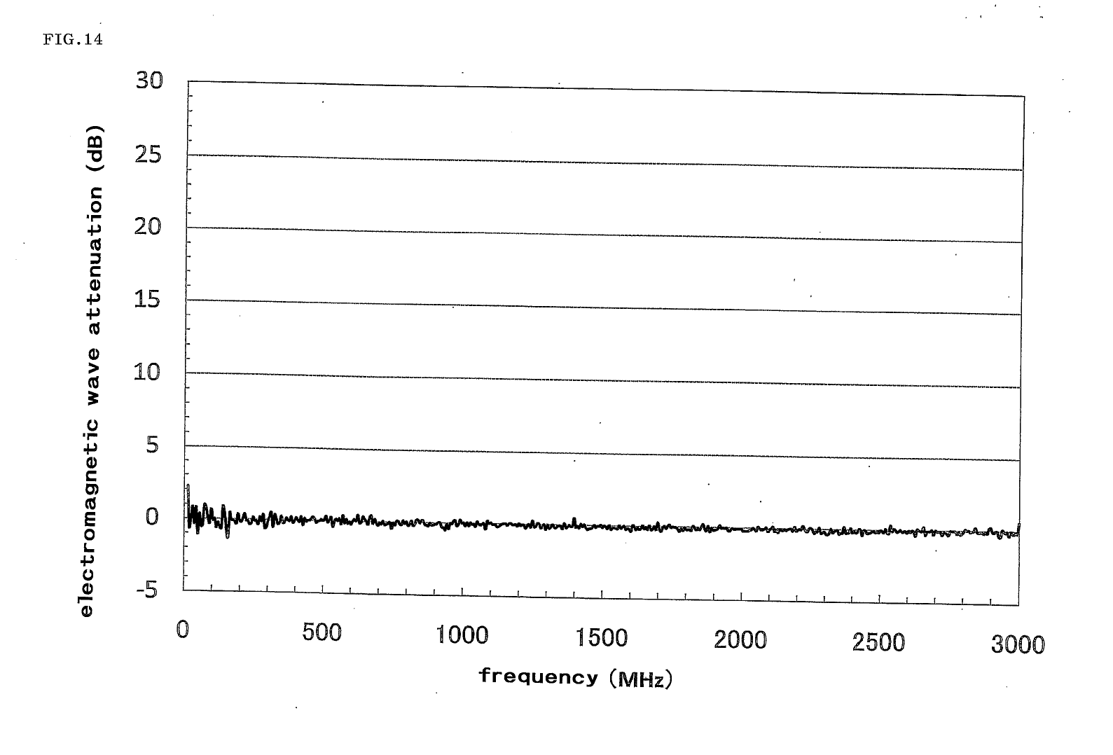

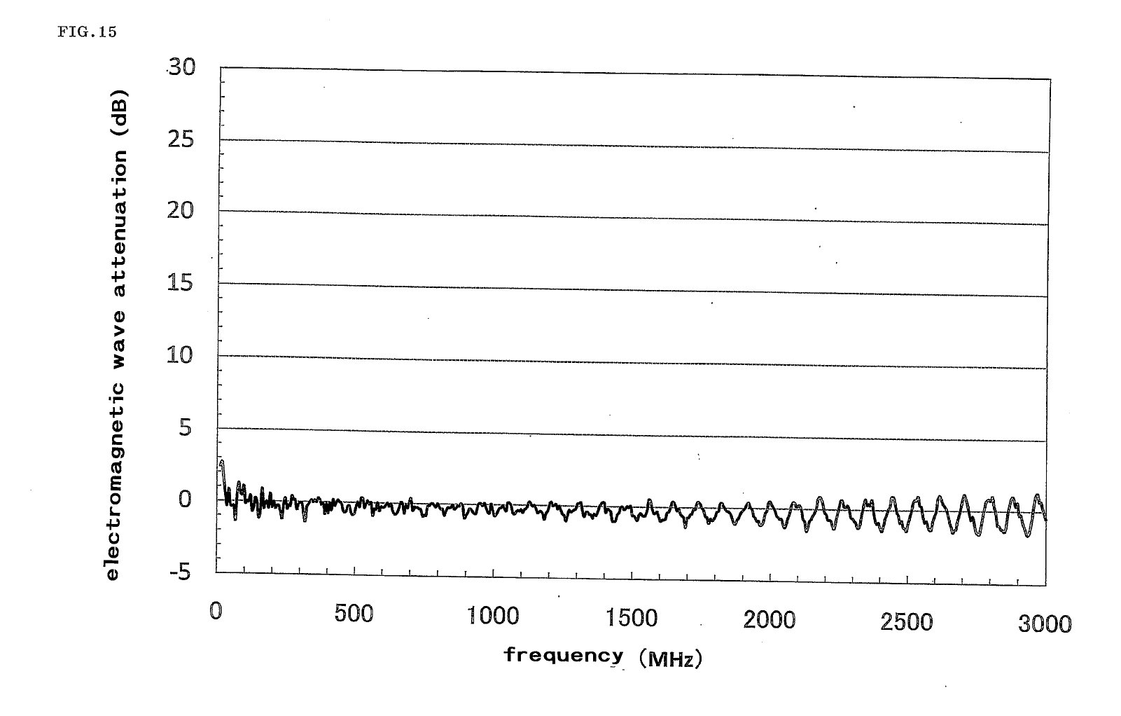

The electromagnetic wave attenuation (dB) of the adhesive films for a semiconductor device according to the examples and comparative examples was measured by a magnetic field probe method. Specifically, a digital signal of a frequency of 13 MHz to 3 GHz was input to a MSL line having a characteristic impedance of 50Ω using a spectrum. analyzer (R3172 manufacture by Advantest Corporation), and then the intensity (dB) of the magnetic field that was generated on 1 mm of the line was measured using a magnetic field probe (CP-2S manufactured by NEC Engineering, Ltd.). Then, the adhesive films for a semiconductor device according to the examples and comparative examples were placed on the MSL line, and the intensity (dB) of the magnetic field was measured. The electromagnetic wave attenuation (dB) in a range of 13 MHz to 3 GHz was obtained by calculating the difference between the measurement value in a state where nothing was placed on the MSL line and the measurement value in a state where the adhesive film for a semiconductor device was placed on the MSL line. The measurement result is shown in Table 1. Graphs that were obtained from the measurement result shown in Table 1 are shown in FIGS. 8 to 15. FIGS. 8 to 13 are each a graph showing the measurement result of Examples 1 to 6 respectively, and FIGS. 14 and 15 are each a graph showing the measurement result of Comparative Examples 1 and 2 respectively.

TABLE 1
Unit: dB

| | | | | | | | Comparative | Comparative |
|---|---|---|---|---|---|---|---|---|
| MHz | Example 1 | Example 2 | Example 3 | Example 4 | Example 5 | Example 6 | Example 1 | Example 2 |
| 13 | 3.23 | 5.84 | 1.31 | 1.95 | 3.55 | 1.89 | 2.20 | 2.43 |
| 19 | 2.81 | 5.28 | 1.05 | 2.08 | 1.90 | 1.09 | −0.59 | 2.67 |
| 31 | 4.30 | 2.34 | 1.27 | 3.28 | 2.60 | 3.48 | 0.80 | 0.42 |
| 43 | 3.76 | 5.15 | 3.35 | 2.83 | 4.06 | 3.73 | 0.76 | 0.78 |
| 55 | 3.35 | 2.93 | 3.66 | 3.10 | 5.15 | 5.13 | 0.30 | −0.38 |
| 103 | 6.70 | 8.73 | 6.18 | 6.34 | 7.41 | 8.18 | −0.10 | −0.16 |
| 151 | 9.17 | 9.21 | 7.59 | 9.38 | 8.59 | 7.21 | −0.63 | −1.15 |
| 205 | 10.65 | 10.20 | 10.41 | 11.04 | 11.49 | 9.35 | −0.20 | −0.03 |
| 301 | 14.52 | 12.64 | 13.63 | 13.05 | 14.40 | 11.66 | −0.12 | −0.12 |
| 403 | 16.27 | 15.79 | 15.90 | 15.84 | 17.30 | 11.70 | 0.14 | −0.78 |
| 505 | 18.63 | 16.97 | 17.53 | 17.27 | 17.21 | 10.15 | 0.10 | −0.29 |
| 601 | 19.24 | 17.49 | 16.89 | 18.03 | 16.90 | 8.81 | −0.20 | −0.31 |
| 703 | 18.09 | 18.49 | 16.32 | 17.11 | 17.36 | 7.49 | −0.08 | 0.32 |
| 805 | 18.96 | 18.78 | 17.48 | 17.52 | 16.95 | 6.05 | −0.23 | −0.20 |
| 901 | 19.27 | 18.26 | 19.98 | 16.72 | 17.55 | 6.09 | −0.11 | −0.78 |
| 1003 | 18.72 | 18.45 | 17.84 | 17.76 | 16.68 | 5.55 | 0.02 | −0.78 |
| 1105 | 19.78 | 17.84 | 19.11 | 17.60 | 17.65 | 5.49 | −0.04 | −0.51 |
| 1201 | 18.48 | 20.44 | 20.87 | 19.01 | 18.04 | 5.18 | 0.04 | −0.01 |
| 1303 | 20.97 | 19.64 | 21.86 | 20.33 | 18.08 | 4.27 | −0.03 | 0.13 |
| 1405 | 15.23 | 17.00 | 19.61 | 17.01 | 16.41 | 4.19 | −0.13 | −0.40 |
| 1501 | 13.06 | 16.29 | 21.36 | 16.86 | 14.80 | 4.64 | −0.14 | −0.59 |
| 1602 | 12.78 | 13.03 | 18.85 | 15.74 | 14.20 | 4.69 | −0.36 | −0.95 |
| 1704 | 16.20 | 15.43 | 21.47 | 15.82 | 14.21 | 5.27 | −0.18 | −0.72 |
| 1800 | 18.59 | 16.17 | 22.02 | 15.43 | 12.50 | 5.60 | −0.19 | −0.61 |
| 1902 | 24.13 | 20.35 | 23.21 | 14.87 | 12.30 | 6.02 | −0.20 | −0.11 |
| 2004 | 20.58 | 19.32 | 23.84 | 13.33 | 11.07 | 6.16 | −0.23 | 0.25 |
| 2100 | 18.24 | 18.25 | 20.84 | 7.30 | 8.70 | 5.53 | −0.12 | 0.21 |
| 2202 | 19.10 | 19.00 | 17.55 | 9.03 | 9.83 | 5.98 | −0.09 | −0.35 |
| 2298 | 17.79 | 18.75 | 17.51 | 12.02 | 11.963 | 5.93 | −0.20 | −0.60 |
| 2400 | 20.97 | 21.48 | 20.95 | 15.72 | 15.28 | 6.41 | −0.22 | −1.26 |
| 2502 | 23.70 | 24.37 | 23.27 | 19.63 | 18.93 | 7.41 | −0.03 | −0.88 |
| 2598 | 24.31 | 23.57 | 22.34 | 20.38 | 18.87 | 8.12 | −0.19 | −0.38 |
| 2700 | 21.21 | 21.82 | 20.27 | 20.36 | 19.27 | 8.33 | 0.00 | 0.78 |
| 2802 | 19.26 | 20.30 | 20.01 | 18.09 | 18.68 | 8.19 | −0.05 | 0.71 |
| 2904 | 19.13 | 17.08 | 17.30 | 18.08 | 17.06 | 8.16 | −0.02 | −0.27 |
| 3000 | 15.73 | 20.89 | 19.15 | 18.25 | 16.73 | 9.31 | 0.58 | −0.51 |

1. An adhesive film for a semiconductor device having an adhesive layer and an electromagnetic wave shielding layer, wherein
the attenuation of the electromagnetic wave that penetrates the adhesive film for a semiconductor device is 3 dB or more in at least a portion of the frequency range of 50 MHz to 20 GHz.

2. A semiconductor device having an adherend and a semiconductor element, wherein
the adhesive film for a semiconductor device according to claim 1 is provided between the adherend and the semiconductor element.

3. A semiconductor device having two or more semiconductor elements, wherein
the adhesive film for a semiconductor device according to claim 1 is provided between one of the semiconductor elements and the remainder of the semiconductor element(s).

4. A semiconductor device in which a semiconductor element is flip-chip connected to an adherend, wherein
the adhesive film for a semiconductor device according to claim 1 is provided on the semiconductor element.

5. The adhesive film for a semiconductor device of claim 1, wherein the adhesive layer comprises a thermosetting resin.

6. The semiconductor device of claim 2, wherein the adherend is a lead frame, a TAB film or a substrate.

7. The semiconductor device of claim 2, wherein the adhesive layer has a shear adhering strength to the semiconductor element of 0.2 to 5 MPa at 17° C.

8. The semiconductor device of claim 2, wherein a 180 peeling adhesive strength between the dicing film and the semiconductor element is 0.5 N/10 mm or more.

9. The semiconductor device of claim 3, wherein the adhesive layer has a shear adhering strength to one of the semiconductor elements of 0.2 to 5 MPa at 17° C.

10. The semiconductor device of claim 3, wherein a 180 peeling adhesive strength between the dicing film and one of the semiconductor elements is 0.5 N/10 mm or more.

11. The semiconductor device of claim 4, wherein the adhesive layer has a shear adhering strength to the semiconductor element of 0.2 to 5 MPa at 17° C.

12. The semiconductor device of claim 4, wherein a 180 peeling adhesive strength between the dicing film and the semiconductor element is 0.5 N/10 mm or more.
